(19) United States
(12) Patent Application Publication
(10) Pub. No.: US 2025/0226233 A1
(43) Pub. Date: Jul. 10, 2025

(54) IN SITU DECLOGGING IN PLASMA ETCHING

(71) Applicant: Lam Research Corporation, Fremont, CA (US)

(72) Inventors: Zhongkui TAN, Fremont, CA (US); Xiaofeng SU, Fremont, CA (US); Mark Naoshi KAWAGUCHI, San Carlos, CA (US); Ji ZHU, Castro Valley, CA (US); Gowri Channa KAMARTHY, Pleasanton, CA (US); Wenchi LIU, Milpitas, CA (US); Priyadarsini SUBRAMANIAN, San Jose, CA (US); Qiang MA, Cupertino, CA (US)

(21) Appl. No.: 18/701,913

(22) PCT Filed: Dec. 14, 2021
(86) PCT No.: PCT/US2021/063406

§ 371 Date: Apr. 16, 2024

Related U.S. Application Data
(60) Provisional application No. 63/262,920, filed on Oct. 22, 2021.

(51) Int. Cl. H01L 21/311; H01L 21/027

(52) U.S. Cl. CPC H01L 21/31116; H01L 21/027

(57) ABSTRACT

In semiconductor processing, plasma etching of materials (e.g., of carbon or silicon) to form vertical high aspect ratio recessed features can lead to clogging inside the recessed features due to unwanted deposition of a mask-derived clogging material (e.g., silicon oxide). This is addressed by declogging, which includes etching the clogging material preferably in the same process chamber by contacting the substrate with a halogen source and a vapor of an organic solvent and/or water. An additive, such as an amine, a heterocyclic compound, or a bifluoride source can be added to increase etch selectivity for the clogging material. After the declogging step, plasma etching proceeds further. The declogging and plasma etching steps can be repeated as many times as needed to etch a recessed feature of desired depth.

### INCORPORATION BY REFERENCE

A PCT Request Form is filed concurrently with this specification as part of the present application. Each application that the present application claims benefit of or priority to as identified in the concurrently filed PCT Request Form is incorporated by reference herein in its entirety and for all purposes.

### FIELD OF THE INVENTION

This invention pertains to methods and apparatuses for semiconductor device manufacturing. Specifically, embodiments of this invention pertain to methods and apparatuses for declogging recessed features during plasma etching in semiconductor processing.

### BACKGROUND

In semiconductor device fabrication, deposition and etching techniques are used for forming patterns of materials, such as for forming metal lines embedded in dielectric layers. Deposition techniques include atomic layer deposition (ALD), chemical vapor deposition (CVD), and physical vapor deposition (PVD). Etching techniques include wet etching methods and dry etching methods, such as plasma etching.

Etching methods may be isotropic and anisotropic. Isotropic etching is characterized by etching in multiple directions on the substrate (both vertical and horizontal), where the etch rates in different directions are substantially the same. Isotropic etching is needed, for example, for horizontal etching. Anisotropic etching is characterized by etching predominantly in one direction, such as in a vertical direction, and is often used for forming recessed features (e.g., vias) on a substrate. Anisotropic etching is also known as “directional etching”.

Directional plasma etching is often used for forming recessed features in a layer of a target material underlying a patterned mask layer. The chemistry of the directional plasma etch is typically selected such that the target material is etched at a higher etch rate than the mask material.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Methods and apparatuses for plasma etching of materials in semiconductor device fabrication are provided. The methods, in some embodiments, allow for efficient directional etching and formation of high aspect ratio recessed features, such as of recessed features with aspect ratios of at least about 5:1, e.g., 5:1-500:1. The methods can be used, for example, in fabrication of 3D NAND devices, dynamic random-access memory (DRAM) devices, and high aspect ratio (HAR) logic devices. The methods, in some embodiments, make use of alternating plasma etching and declogging steps, where the declogging steps at least partially remove a clogging material that narrows the recessed features and interferes with plasma etching.

In one aspect, a method of etching a material on a semiconductor substrate is provided. In some embodiments the method includes: providing a semiconductor substrate having an exposed layer of a mask material, a recessed feature, and a layer of a target material underlying the layer of the mask material, wherein the target material is exposed at the bottom of the recessed feature; etching the target material using a plasma etch (e.g., using an oxygen-containing reactant), and thereby increasing depth of the recessed feature, wherein the etching of the target material results in narrowing or blocking of the recessed feature at least at one location due to deposition of a clogging material (e.g., silicon oxide); and etching the clogging material by contacting the semiconductor substrate with a halogen source and a vapor of a liquid selected from the group consisting of an organic solvent and water. In some embodiments, the halogen source includes at least one of nitrogen tribromide (NBr₃), nitrogen trichloride (NCl₃), chlorine trifluoride (ClF₃), hydrogen fluoride (HF), hydrogen chloride (HCl), and hydrogen bromide (HBr). The organic solvent in some embodiments includes at least one of an alkane, a ketone, and an alcohol.

In some embodiments the etching of the target material and the etching of the clogging material are performed in one processing chamber. The etching of the target material and the etching of the clogging material can be repeated as many times as desired. In some embodiments the target material is at least one of carbon (e.g., amorphous carbon) and silicon. The mask material in some embodiments is selected from the group consisting of silicon oxynitride, silicon nitride, silicon oxide, silicon oxycarbide, silicon boride, boron-doped carbon, tungsten, tungsten-doped carbon, and boron-doped carbon.

In some embodiments the etching of the clogging material has an etch selectivity of greater than 1 to both the mask material and the target material and is performed in an absence of plasma. In other embodiments, selective etching of the clogging material includes activating at least one reactant in a plasma without externally biasing the semiconductor substrate. Etching of the clogging material can be performed by simultaneously contacting the semiconductor substrate with the halogen source and the vapor of a liquid selected from the group consisting of the organic solvent and water. In other embodiments, the etching of the clogging material includes sequentially contacting the semiconductor substrate with the halogen source and the vapor of a liquid selected from the group consisting of the organic solvent and water. The etching of the clogging material may further include contacting the semiconductor substrate with an additive selected from the group consisting of an amine, a heterocyclic compound and a bifluoride source. Etching of the clogging material can be conducted at a pressure of between about 0.01-10 Torr and a temperature of between about −60-250° C.

In some embodiments, the recessed feature of the semiconductor substrate provided for etching has a width of about 5-300 nm, and has an aspect ratio after completion of the etching of at least about 5:1. In some embodiments, the semiconductor substrate is selected from a group consisting of a partially fabricated 3D NAND device, a DRAM device, and a logic device.

In some embodiments the method further includes the steps of applying photoresist to the semiconductor substrate; exposing the photoresist to light; patterning the photoresist and transferring the pattern to the semiconductor substrate; and selectively removing the photoresist from the semiconductor substrate.

In one aspect a method of etching a material on a semiconductor substrate is provided, where the method includes: (a) providing a semiconductor substrate having an exposed layer of a mask material, a recessed feature, and a layer of a target material underlying the layer of the mask material, wherein the target material is exposed at the bottom of the recessed feature, wherein the mask material is a silicon-containing material, and wherein the target material is selected from the group consisting of carbon (C) and silicon (Si); (b) etching the target material using an oxygen-containing plasma etch, and thereby increasing depth of the recessed feature, wherein the etching of the target material results in narrowing or blocking of the recessed feature at least at one location due to deposition of a silicon-containing clogging material (e.g., silicon oxide); and (c) etching the silicon-containing clogging material by contacting the semiconductor substrate with a halogen source and a vapor of a liquid selected from the group consisting of an organic solvent and water.

In one aspect, an apparatus for processing a semiconductor substrate is provided. In some embodiments, the apparatus includes: (a) a process chamber configured for housing the semiconductor substrate, wherein the process chamber includes a substrate holder configured to hold the semiconductor substrate, and an inlet configured to admit one or more reactants to the process chamber; (b) a plasma generating mechanism; (c) a mechanism for vaporising a liquid connected with the process chamber and configured for delivering the vaporised liquid to the process chamber; and (c) a controller comprising program instructions configured to effect etching of a material on the semiconductor substrate. In some embodiments the program instructions are configured to effect etching by causing: (i) on a semiconductor substrate comprising an exposed layer of a mask material, a recessed feature, and a layer of a target material undelying the layer of the mask material, wherein the target material is exposed at a bottom of the recessed feature, etching of the target material using a plasma etch, and thereby causing an increase in depth of the recessed feature; and (ii) etching of a clogging material deposited during the plasma etch and narrowing or blocking the recessed feature, by causing contact of the semiconductor substrate with a halogen source and a vapor of a liquid selected from the group consisting of an organic solvent and water. In some embodiments the program instructions include instructions configured to repeat etching of the target material and etching of the clogging material. In some embodiments the program instructions are configured for causing activation of an oxygen-containing reactant in a plasma during the plasma etch.

In another aspect, a non-transitory machine-readable medium is provided, which includes machine-readable code for performing any of the methods described herein. For example, machine-readable medium may include code for: (i) on a semiconductor substrate comprising an exposed layer of a mask material, a recessed feature, and a layer of a target material undelying the layer of the mask material, wherein the target material is exposed at a bottom of the recessed feature, etching of the target material using a plasma etch, and thereby causing an increase in depth of the recessed feature; and (ii) etching of a clogging material deposited during the plasma etch and narrowing or blocking the recessed feature, by causing contact of the semiconductor substrate with a halogen source and a vapor of a liquid selected from the group consisting of an organic solvent and water.

These and other aspects of implementations of the subject matter described in this specification are set forth in the accompanying drawings and the description below.

### BRIEF DESCRIPTION OF THE DRAWINGS

FIGS. 1A-1D provide schematic cross-sectional views of a portion of a substrate undergoing processing according to an embodiment provided herein.

FIG. 2 is a process flow diagram for etching with declogging according to an embodiment provided herein.

FIG. 3 is a process flow diagram for declogging according to an embodiment provided herein.

FIG. 4 is a schematic presentation of an apparatus that is suitable for plasma etching and declogging, according to an embodiment provided herein.

FIG. 5 is a diagram illustrating vapor delivery to the process chamber, according to an embodiment provided herein.

FIG. 6 is a schematic presentation of a system that is suitable for implementing methods provided herein.

### DETAILED DESCRIPTION OF THE PREFERRED EMBODIMENTS

Methods and apparatuses for etching are provided. The provided methods can be used in a variety of applications but are particularly useful for directional plasma etching of materials to form high aspect ratio recessed features on semiconductor substrates. For example, provided methods can be used for forming recessed features with widths of between about 5-300 nm (e.g., 10-200 nm), and aspect ratios of at least about 5:1 (e.g., between about 5:1-500:1), such as at least about 10:1, at least about 50:1 or at least 100:1. The methods can be used, for example, in fabrication of 3D NAND devices, DRAM devices, and high aspect ratio (HAR) logic devices. In some embodiments, the methods are used for forming recessed features with widths of between about 5-30 nm in fabrication of DRAM devices and HAR logic devices.

Plasma etching in semiconductor device fabrication to form high aspect ratio recessed features is often hampered by inadvertent deposition of a clogging material in the recessed features. Clogging can slow down the plasma etching process and can lead to increased non-uniformity. Provided methods allow for fast in situ declogging with minimal changes to critical dimensions of the recessed features.

Deposition of the clogging material, as used herein, may include but is not limited to redistribution of material from other parts of the substrate into the recessed feature (e.g., by sputtering), chemical modification of any of substrate's materials to form a clogging material, and a combination of redistribution and chemical modification. For example, the clogging material may be derived from a mask material and/or from a target layer material. In some embodiments the clogging material has a similar composition to the materials of the substrate (e.g., mask material), but is more porous. For example, in some embodiments, silicon oxide mask material may be sputtered and redistributed during plasma etching and form a more porous silicon oxide clogging material inside a recessed feature.

“Clogging”, as used herein, refers to narrowing of the recessed feature or blockage of the recessed feature at any location, such as near the opening of the recessed feature, due to deposition of the clogging material. For example, a diameter of the recessed feature at the clogging location may be reduced by at least about 10%, such as by at least about 20%. Clogging material in some embodiments is selected from the group consisting of: oxides (e.g., silicon oxide, tin oxide, etc.), nitrides (e.g., silicon nitride, tantalum nitride, titanium nitride, etc.), carbides (e.g., silicon carbide, etc.), carbonitrides (e.g., silicon carbonitride, etc.), oxycarbides (e.g., silicon oxycarbide, etc.), etc. In some embodiments, the clogging material is a silicon-containing material, such as a material that includes silicon (Si) and oxygen (O). In some embodiments, clogging material is silicon oxide (SiO). Other silicon-containing materials that include silicon and oxygen are silicon oxynitride (SiON), silicon oxycarbide (SiOC), silicon oxycarbonitride (SiOCN), etc.

In the description of material layers (e.g., SiO, SiON, Si, C, etc.) the formulas are not indicative of the stoichiometry, which may vary. The materials include the elements listed in their respective formulas, and, optionally, hydrogen (H). Other elements may be present as dopants in small concentrations that are typically not more than 20 atomic % (excluding hydrogen), such as not more than 10 atomic % (excluding hydrogen), or not more than 5 atomic % (excluding hydrogen).

In some embodiments, the clogging material is formed from any material of the semiconductor substrate (e.g., mask material and/or target material) with or without chemical modification. For example, the clogging material may be formed from a silicon-containing material such as silicon (Si), silicon oxide (SiO), silicon nitride (SiN), silicon oxynitride (SiON), silicon carbide (SiC), and silicon oxycarbide (SiOC). In some embodiments, the clogging material is an oxygen-containing material, and is formed, when the semiconductor substrate is exposed to an oxygen-containing reactant, such as O₂, O₃, CO₂, CO,.COS, and H₂O, where the oxygen-containing reactant may be activated in a plasma. For example, an oxygen-containing clogging material (e.g., silicon oxide), may be formed from silicon oxynitride, or silicon oxycarbide when these materials are exposed to a plasma etch chemistry that includes oxygen-containing reactants. For example, when a silicon-containing mask material is used on a substrate that undergoes plasma etching with an oxygen-containing reactant, a silicon oxide clogging material may form due to redistribution and/or chemical modification of the mask material.

The term “semiconductor substrate” as used herein refers to a substrate at any stage of semiconductor device fabrication containing a semiconductor material anywhere within its structure. It is understood that the semiconductor material in the semiconductor substrate does not need to be exposed. Semiconductor wafers having a plurality of layers of other materials (e.g., dielectrics) covering the semiconductor material, are examples of semiconductor substrates. The following detailed description assumes the disclosed implementations are implemented on a semiconductor wafer, such as on a 200 mm, 300 mm, or 450 mm semiconductor wafer. However, the disclosed implementations are not so limited. The semiconductor wafer may be of various shapes, sizes, and materials. In addition to semiconductor wafers, other types of work pieces may take advantage of the disclosed implementations including various articles such as printed circuit boards and the like.

The term “about” when used in reference to numerical values includes a range of ±20% of the recited numerical value, unless otherwise specified.

The term “a” is used herein to specify “one or more”. For example, “a recessed feature” should be interpreted as “one or more recessed features”.

Provided methods employ one or more declogging steps alternating with plasma etching steps, where declogging is preferably performed in the same process chamber as the plasma etching steps (in situ declogging). Since it is not necessary to move the substrate to a different process chamber for declogging, the entire etching process can be conducted in a fast and efficient manner. Another advantage of provided methods is that external electrical biasing of the substrate is not required during the declogging step, since provided declogging chemistries can be used to etch the clogging material without external bias and even in an absence of plasma activation. Declogging without biasing the substrate can advantageously lead to reduced damage of the substrate and to smaller variation in the critical dimensions of a recessed feature.

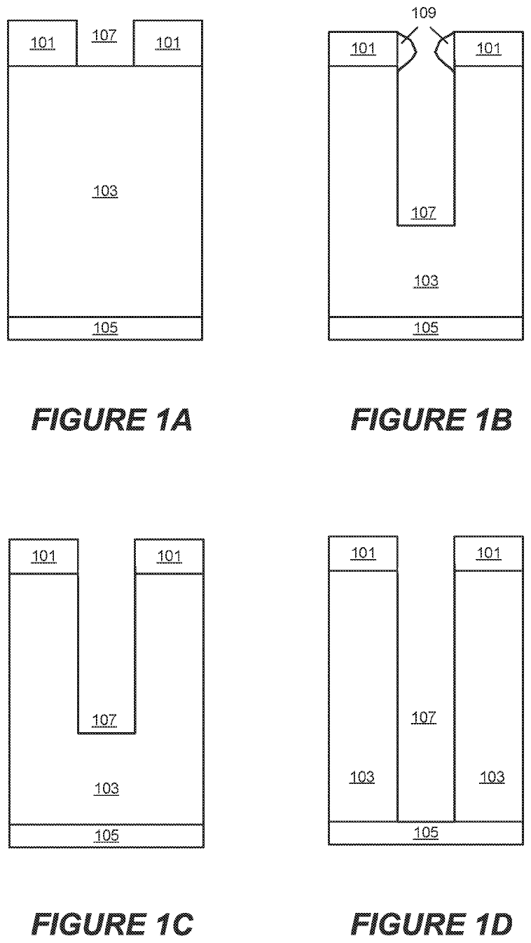

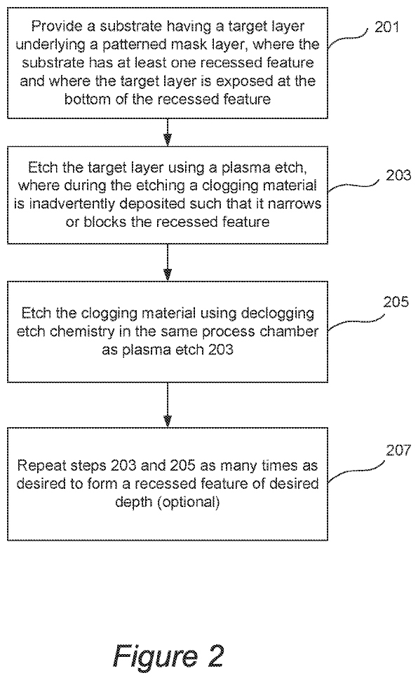

Declogging during plasma etching, according to some embodiments, is illustrated in FIGS. 1A-1D and in FIG. 2. FIGS. 1A-1D show schematic cross-sectional views of a portion of a semiconductor substrate during processing, according to embodiments provided herein. It is noted that FIGS. 1A-1D illustrate a portion of the substrate and show one recessed feature, but it is understood that the substrate may include a plurality of recessed features, as well as a plurality of underlying layers (not shown). FIG. 2 is a process flow diagram illustrating the steps of the processing method, according to the embodiment illustrated by FIGS. 1A-1D. The process starts in step 201 by providing a substrate having a target layer underlying a patterned mask layer, where the substrate has at least one recessed feature, and where the target layer is exposed at the bottom of the recessed feature. An example of such substrate is shown in FIG. 1A, where a patterned mask layer 101 overlies the target layer 103, which is, in turn, disposed over an etch stop layer 105. The substrate includes a recessed feature 107, where the target material of the target layer 107 is exposed at the bottom of the recessed feature 107. In some embodiments the width of the recessed feature 107 is about 5-300 nm, such as about 10-100 nm. In some embodiments, (e.g., in DRAM device fabrication or in HAR logic device fabrication) the width of the recessed feature is about 5-30 nm.

The materials of the mask layer 101 and of the target layer 103 are preferably selected such that for the target material etching, the etch selectivity is greater than 1, such as greater than 2, relative to the mask material, in the desired etch direction. The material of the etch stop layer 105 is preferably selected such that for the target material etching, the etch selectivity is greater than 1, such as greater than 2, relative to the etch stop material. Examples of target materials, without limitation, include carbon (e.g., amorphous carbon), silicon (e.g., polycrystalline silicon, amorphous silicon, and doped silicon), and other silicon-containing materials. Examples of mask materials include, without limitation, silicon-containing materials, such as silicon nitride (SiN), silicon oxynitride (SiON), silicon oxide (SiO), silicon carbide (SiC), silicon oxycarbide (SiOC), silicon boride (SiB); tungsten-containing materials, such as tungsten (W), and carbon-containing materials, such as tungsten-doped carbon (WC), and boron-doped carbon (BC). The thickness of the mask layer 101 is typically smaller than the thickness of the target layer 103. In some embodiments, the mask layer 101 is between about 10-1500 nm thick, and the target layer 103 is between about 50-1000 nm thick.

The material of the target layer 103 on the provided substrate is exposed such that it is accessible to gaseous reactants. The substrate is processed in any suitable apparatus having a process chamber equipped with a substrate holder (e.g., a pedestal) and an inlet for introduction of reactants, where the apparatus is configured for generating a plasma directly in the process chamber or remotely. Referring to step 203 of FIG. 2, the process follows by etching the target layer 103 using a plasma etch, where during the etching, a clogging material is inadvertently deposited such that it narrows or blocks the recessed feature. The resulting substrate is shown in FIG. 2B, where the clogging material 109 is deposited on the sidewalls of the recessed feature 107 during plasma etching of the target layer 103. In the depicted example, the clogging material narrows the recessed feature 107 at the feature opening, as it is deposited primarily on the mask layer 101, but in other cases the clogging material may be deposited deeper inside the recessed feature 107. The inadvertently deposited clogging material 109, if not removed, hampers contact of the plasma etch chemistry with the target layer 103 at the bottom of recessed feature 107, which, in turn, may lead to slower (or even halted) etching, and lower etching uniformity. For example, circular holes may have deviations from circularity, and lower local critical dimension uniformity (LCDU), if clogging material is allowed to remain in the recessed feature.

The process follows in step 205 by etching the clogging material using a declogging etch chemistry in the same process chamber as the plasma etch of the target layer. The declogging is preferably performed by contacting the substrate with gaseous reactants under vacuum. In some embodiments, the first declogging step is initiated after at least about 5%, such as at least about 10%, at least about 20%, at least about 30%, at least about 40% of the target depth of the recessed feature has been etched by the plasma etch. In some embodiments etching the clogging material using the declogging chemistry includes exposing the clogging material to a halogen source (in gas phase) and a vapor of an organic solvent and/or water vapor, where the declogging chemistry may further include an additive for improving etching uniformity. Etching of the clogging material may be partial or complete. The structure obtained after complete removal of the clogging material is illustrated in FIG. 1C, which shows that the clogging material 109 is absent, and the width of the recessed feature 107 is restored. It is understood, that in some embodiments, complete removal of the clogging material is not required, and only a portion of the clogging material may be etched to widen the recessed feature. The declogging etch chemistry in some embodiments is selective to both the mask material and the target material (i.e., etches the clogging material at a higher rate than both the mask material and the target material). In some embodiments, the etch selectivity is at least about 2 relative to both the mask material and the target material.

Next, in step 207, the plasma etching of the target material, and the etching of the clogging material are optionally repeated as many times as desired to form a recessed feature of desired depth. For example, the etching process may include 2-21 cycles, e.g. 2-10 cycles, where each cycle includes one target material etching step and one declogging step. In some implementations each target material etching step removes between about 10-300 nm of target material. Recessed features in the target material with depths of between about 100-2000 nm and high aspect ratios of at least about 5:1 can be formed without changing a process chamber by provided methods. In some embodiments, it is preferred to etch the declogging material in an absence of plasma (thermal declogging). In other embodiments the process may be plasma-assisted. In some embodiments, etching of the clogging material is performed without applying an external bias to the semiconductor substrate in order to reduce the possibility of substrate damage due to interaction of ions with the substrate. Referring to FIG. 1D, a substrate after completed etching of the target layer 103 has the recessed feature 107 extending to the etch stop layer 105, which is exposed at the bottom of the feature. Depending on the size of the required recessed feature and the nature of the clogging, the etch may be completed in one etch cycle having a single target material etch step followed by the declogging step, or several cycles of alternating steps. If desired, the process chamber may be purged between the target material etching step and the declogging step. In some embodiments, the entire etching process is performed at one temperature and/or pressure. In other embodiments temperature and/or pressure of the target material etching step is different from those of the declogging step. The process temperature used for both steps, in some embodiments is between about −60-250° C., such as between about 0-175° C. In some embodiments pressures of between about 0.01-10 Torr are used for both steps.

In some embodiments, plasma etching step includes introducing an etching process gas into the process chamber housing the substrate, where the process gas includes a reactant gas (e.g., an oxygen-containing reactant gas and/or a halogen-containing reactant gas) and, optionally, a carrier gas (e.g., nitrogen, helium, argon, etc.), and forming a plasma to activate the reactant in a plasma while also providing an external bias to the substrate to effect directional etching of the target material. Next, the flow of the reactant gas is stopped, the external bias to the substrate is turned off, and, without breaking the vacuum, a declogging composition is introduced into the process chamber. In some embodiments, the plasma is turned off for the declogging step, and the declogging step is performed thermally.

The declogging step in some embodiments is conducted by exposing the substrate to a declogging gas that includes a halogen source and a vapor of organic solvent (and/or water vapor). The declogging gas may also include a carrier gas. In some embodiments, the declogging gas includes an additive for improving etch selectivity.

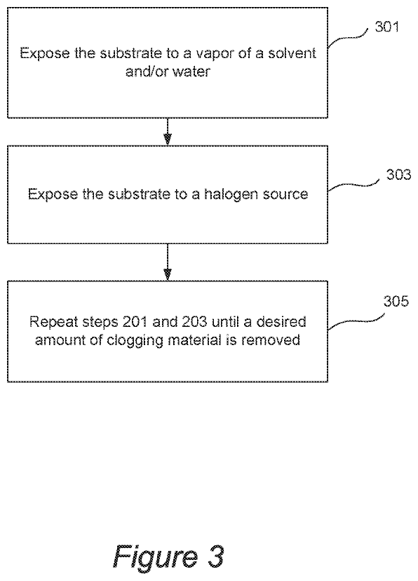

In some embodiments the halogen source and a vapor of organic solvent (and/or water vapor) are introduced into the process chamber sequentially. An additive, when used, is typically introduced together with the vapor of organic solvent (and/or water vapor). A carrier gas can also be included. These embodiments are illustrated by the process flow diagram of FIG. 3. In step 301 the substrate in the declogging step is exposed to the vapor of an organic solvent and/or water, optionally, with an additive for a period of time, in an absence of a halogen source. Next, after a layer of solvent and/or water (e.g., adsorbed layer) is formed on the substrate, the substrate is exposed to a halogen source in step 303 and the declogging etching is allowed to proceed. In some embodiments the exposure of the substrate to the halogen source is accompanied with activation of the halogen source in a plasma, while exposure of the substrate to solvent and/or water is performed in an absence of plasma. Next, referring to step 305, the exposure to solvent and/or water and exposure to the halogen source are repeated optionally as many times as needed to remove a desired amount of the clogging material and complete the declogging step. For example, each declogging step may include 2-20 cycles, where each cycle includes one solvent and/or water exposure and one exposure to the halogen source.

In one illustrative embodiment, referring to FIG. 1A the target layer 103 is a carbon layer (e.g., an amorphous carbon layer), and the mask layer 101 is a silicon-containing layer, such as silicon oxynitride (SiON) layer. The etch stop layer 105 may also be a silicon-containing layer, such as a silicon oxide layer. In one example, the thickness of the mask layer 101 is about 300 nm, the thickness of the target layer is about 3000 nm and the thickness of the etch stop layer is about 200 nm. The process starts by plasma etching the carbon-containing target layer using a plasma etch chemistry that is selective relative to both the mask material and the etch stop material. For example, the substrate may be exposed to an oxygen-containing reactant activated in a plasma. Examples of suitable oxygen-containing reactants include O₂, COS, SO₂ and any combination thereof. The plasma etching process gas, in addition to the oxygen-containing reactant may include additives and a carrier gas. In some embodiments, the plasma is formed using an inductively coupled plasma (ICP) source. The plasma density is controlled by the plasma source power. The etching in this example also utilizes a bias provided to the substrate, since anisotropic vertical etching is desired. Examples of frequencies used for the ICP source are 2 MHz, 13 MHZ, 27 MHz, and 60 MHz. Examples of frequencies used for the bias are 400 KHz, 1 MHz, 2 MHZ, 13 MHz, 27 MHz, and 60 MHz.

As the etching of the target material proceeds (e.g., after 200-2000 nm is etched), the silicon-containing mask material will be sputtered off and redeposited on the sidewalls of the recessed feature forming the clogging material. In some cases the material may be chemically modified. For example, when a silicon oxynitride mask is used, the re-deposited silicon oxynitride material may react with the oxygen-containing reactant to form a porous silicon oxide clogging material at the opening of the recessed feature, as shown in FIG. 1B. Next, without breaking the vacuum, the porous silicon oxide clogging material is etched by exposing the substrate to a halogen source, a vapor of an organic solvent (and/or water vapor), and, optionally, an additive (e.g., a an amine, a heterocyclic compound or a bifluoride source) without externally biasing the substrate. In some embodiments the clogging material is etched in an absence of plasma. In other embodiments, the declogging is plasma-assisted. After the declogging, the oxygen-containing plasma etch of the carbon-containing target layer may resume without breaking the vacuum in the same process chamber and can continue until clogging material is built up again, whereupon the plasma etching and declogging steps may be repeated in an alternating manner as many times as desired.

In another illustrative embodiment, the target layer 103 is silicon (e.g., polycrystalline silicon, amorphous silicon, or doped silicon), and the mask material is a silicon-containing mask, such as silicon oxide, silicon oxynitride, silicon nitride, silicon carbide, etc. The silicon target material is etched anisotropically with a plasma formed in a process gas that includes a halogen source (e.g., Cl₂, HBr, a fluorocarbon, or a combination thereof) and an oxygen source (e.g., O₂), where the oxygen source is used to control the etch profile. The etching of the silicon target material in this case results in deposition of a silicon oxide clogging material and narrowing of the recessed feature, where the clogging material is derived from the mask material (e.g., via redistribution and/or chemical modification with O₂). Next, the clogging material is etched using a declogging chemistry as described herein with or without plasma activation.

In both examples, the declogging etch is selective for the clogging material relative to both the mask material and the target material. In some embodiments the etch selectivity for the target material in the desired direction relative to both the mask material and the target material is greater than 1.5, such as greater than 2. For example, a silicon oxide clogging material is selectively etched in a desired direction relative to both carbon target layer and a silicon oxynitride mask layer. It is noted that when both the clogging material and the mask material are silicon oxide, the declogging can still proceed selectively, because the clogging silicon oxide material is typically more porous and is more easily etched than the silicon oxide of the mask material (e.g., CVD-deposited silicon oxide). In another example, the silicon oxide clogging material is selectively etched in a desired direction relative to a silicon target material and to a silicon oxide or silicon oxynitride mask material.

### Declogging Chemistry

Declogging is typically performed in the same process chamber as the plasma etch and includes exposing the substrate to a halogen source in gas phase, and a vapor of an organic solvent and/or water vapor to etch the clogging material. An additive, such as an amine, a heterocyclic compound or a bifluoride source can be added to improve the etch selectivity for the clogging material. An inert carrier gas may also included. The reactants are provided to the reaction chamber and exposed to the substrate while they are in vapor phase. Appropriate hardware may be provided to ensure that the reactants are adequately vaporized before and during delivery to the reaction chamber. Two or more of the reactants may be mixed before delivery to the reaction chamber. In other embodiments, each of the reactants may be delivered to the reaction chamber individually, for example in separate lines or at separate times.

### Halogen Source

The halogen source may be any halogen-containing (e.g., X-containing, where X is fluorine (F), chlorine (Cl), bromine (Br), or iodine (I)) compound that exists in vapor phase at the processing temperature. Examples include hydrogen bromide (HBr), hydrogen chloride (HCl), hydrogen fluoride (HF), fluorine (F₂), chlorine (Cl₂), bromine (Br₂), chlorine trifluoride (ClF₃), nitrogen trifluoride (NF₃), nitrogen trichloride (NCl₃), and nitrogen tribromide (NBr₃). In some implementations, the halogen source is an organohalide, with examples including fluoroform (CHF₃), chloroform (CHCl₃), bromoform (CHBr₃), carbon tetrafluoride (CF₄), carbon tetrachloride (CCl₄), carbon tetrabromide (CBr₄), perfluorobutene (C₄F₈), and perchlorobutene (C₄Cl₈). In some implementations, the halogen source is a silicon halide, with examples including silicon tetrafluoride (SiF₄), silicon tetrachloride (SiCl₄), silicon tetrabromide (SiBr₄), and compounds that include SiX₆ such as H₂SiX₆. In some implementations, the halogen source is a metal halide with examples including molybdenum hexafluoride (MoF₆), molybdenum hexachloride (MoCl₆), molybdenum hexabromide (MoBr₆), tungsten hexafluoride (WF₆), tungsten hexachloride (WCl₆), tungsten hexabromide (WBr₆), titanium tetrafluoride (TiF₄), titanium tetrachloride (TiCl₄), titanium tetrabromide (TiBr₄), zirconium fluoride (ZrF₄), zirconium chloride (ZrCl₄), and zirconium bromide (ZrBr₄). Metal halides may be used in some embodiments to selectively etch metal oxides.

In the description below, various examples include HF as the halogen source. However, any appropriate halogen source may be used. The volume and mass percentages described for HF can be used for other halogen sources. In some embodiments, two or more halogen sources may be used.

### Organic Solvent

### Alkanes:

In some embodiments, the organic solvent may be an alkane. In certain embodiments, the alkane may be an acyclic branched or unbranched hydrocarbon having the general formula CₙH₂ₙ₊₂. Example acyclic alkanes include, but are not limited to, pentane, hexane, octane, and combinations thereof. In certain other embodiments, the alkane may be a cyclic hydrocarbon. Example cyclic hydrocarbons include, but are not limited to, cyclopentane, cyclohexane, and combinations thereof.

### Aromatic Solvents:

In some embodiments, the organic solvent may be an aromatic solvent. As used herein, “aromatic” means a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Hückel rule (4n+2). The point of attachment to the parent structure typically is through an aromatic portion of the condensed ring system. In some cases, an aromatic solvent may be selected from toluene and benzene.

### Alcohols:

In certain implementations, the organic solvent may be an alcohol. The alcohol can be an alcohol having a formula of X—C(R)ₙ(OH)—Y, where:
n is 1;
each X and Y can be independently selected from hydrogen, —[C(R¹)₂]ₘ—C(R²)₃, or OH, wherein each R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10; and each R independently is selected from hydrogen, hydroxyl, aliphatic, haloaliphatic, haloheteroaliphatic, heteroaliphatic, aromatic, aliphatic-aromatic, heteroaliphatic-aromatic, or any combinations thereof.

In some embodiments, each R,R¹ and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the alcohol may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In other embodiments, when at least one of X or Y=—[C(R¹)₂]ₘ—C(R²)₃ or R is a hydrogen and m is 1, the alcohol can be a C₃ alcohol. For instance, if at least one R¹ and one R² is absent, then the C₃ alcohol can be a C₃ alkenol (e.g., allyl alcohol). In another instance, R and one R² together can form a ring (such as, cycloaliphatic), then the C₃ alcohol can be a cyclopropanol or 2-cyclopropenol.

In yet other embodiments, when at least one of X or Y=—[C(R¹)₂]ₘ—C(R²)₃ or R is a hydrogen and m is 2, the alcohol can be a C₄ alcohol. For instance, if at least one R¹ and one R² is absent, then the C₄ alcohol can be a C₄ alkenol (e.g., 2-buten-1-ol or 3-buten-1-ol). In another instance, R and one R² together can form a ring (such as, cycloaliphatic), then the C₄ alcohol can be a C₄-cyclic alcohol (e.g., cyclobutanol or a cyclopropylmethanol). In yet another instance, if both X and Y are not OH, then the C₄ alcohol can be a C₄-branched alcohol (e.g., 2-butanol, isobutanol, or tert-butanol).

In some instances, when X=OH and Y=—[C(R¹)₂]ₘ—C(R²)₃, the alcohol can be a diol. In other instances, when at least one X or Y=—[C(R¹)₂]ₘ—C(R²)₃ and at least one R¹═OH or one R²═OH, or when R═OH, the alcohol can be a diol. Example diols include, but are not limited to, 1,4-butane diol, propylene-1,3-diol, and the like.

In other instances, when X═Y═OH, the alcohol can be a triol. In yet other instances, when X═R═OH, the alcohol can be a triol. In some instances, when at least one of X or Y is —[C(R¹)₂]ₘ—C(R²)₃ and one R¹ and at least one R² is OH, the alcohol can be triol. In other instances, when R=OH and X=—[C(R¹)₂]ₘ—C(R²)₃ and one R¹ and at least one R² is OH, the alcohol can be triol. Example triols include, but are not limited to, glycerol or glycerine derivatives thereof.

In particular embodiments, when R=cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol (e.g., an optionally substituted heterocyclyl substituted with or more hydroxyls, such as furfuryl alcohol) In other embodiments, when at least one of X or Y is —[C(R¹)₂]ₘ—C(R²)₃ and one R¹ and at least one R² is cycloheteroaliphatic, heterocyclyl, heteroaryl, alkyl-heterocyclyl, alkenyl-heterocyclyl, alkynyl-heterocyclyl, heteroalkyl-heterocyclyl, heteroalkenyl-heterocyclyl, or heteroalkynyl-heterocyclyl, the alcohol can be a heterocyclyl alcohol.

In various embodiments, the alcohol may have between 1-10 carbon atoms. The alcohol may be a primary alcohol, a secondary alcohol, or a tertiary alcohol. In some cases, the alcohol may be selected from the group consisting of: methanol, ethanol, 1-propanol, 2-propanol, 1-butanol, 2-butanol, t-butanol, 1-pentanol, 1-hexanol, 1-heptanol, 1-octanol, 1-nonanol, 1-decanol, and combinations thereof.

### Laboratory Solvents:

In these or other cases, the organic solvent may include a laboratory-type solvent such as acetonitrile, dichloromethane, carbon tetrachloride, or a combination thereof.

### Ketones:

In some embodiments, the organic solvent may be a ketone.

The organic solvent can also be a ketone having a formula of X—[C(O)]ₙ—Y, where:
n is an integer from 1 to 2;
each X and Y can be independently selected from —C(R¹)₃, —R², or —[C(R³)₂]ₘ—C(O)—R⁴, wherein each R¹, R², R³ and R⁴ can be independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof,
in which R³ and R⁴, taken together with the atom to which each are attached, can optionally form a cycloaliphatic or cycloheteroaliphatic, and in which X and Y, taken together with the atom to which each are attached, can optionally form a cycloaliphatic or cycloheteroaliphatic; and
m is an integer from 0 to 10.

In some embodiments, each R¹, R², R³ and R⁴, independently, are alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the organic solvent may further be substituted with one or more substituents, such as aldehyde (—C(O)H), oxo (═O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof. One example ketone is acetone.

In some embodiments, when X and Y, taken together with the atom to which each are attached, forms a cycloaliphatic or cycloheteroaliphatic, the organic solvent can be a cyclic ketone. Example cyclic ketones include cyclohexanone, cyclopentanone, and the like.

In other embodiments, when at least one of X or Y=—[C(R³)₂]ₘ—C(O)—R⁴, the organic solvent can be a diketone. Example diketones include diacetyl, 2,3-pentanedione, 2,3-hexanedione, 3,4-hexanedione, acetylacetone, acetonylacetone, and the like, as well as halogenated forms thereof, such as hexafluoroacetylacetone.

In further embodiments, when at least one of X or Y=—[C(R³)₂]ₘ—C(O)—R⁴ and X and Y, taken together with the atom to which each are attached, forms a cycloaliphatic or cycloheteroaliphatic, the organic solvent can be a cyclic diketone. Example cyclic diketones include dimedone, 1,3-cyclohexanedione, and the like.

In some instances, when X=—CH₃, the organic solvent can have Y=—C(R¹)₃, in which at least one R¹ is C₂₋₁₀ hydroxyl, aliphatic, haloaliphatic, haloheteroaliphatic, heteroaliphatic, aromatic, aliphatic-aromatic, heteroaliphatic-aromatic, or any combinations thereof. Example materials can include methyl propyl ketone, methyl butyl ketone, hydroxyacetone, and the like.

In other instances, when X=—CH₃, the organic solvent can have Y=—R², in which at least one R² is C₂ alkenyl, C₃₋₁₀ aliphatic, haloaliphatic, haloheteroaliphatic, heteroaliphatic, aromatic, aliphatic-aromatic, heteroaliphatic-aromatic, or any combinations thereof. Example materials can include methyl vinyl ketone, methyl propyl ketone, methyl butyl ketone, and the like.

In yet other instances, when at least one of X or Y=aromatic, or aliphatic-aromatic, or heteroaliphatic-aromatic, the organic solvent can be an aromatic ketone. Example materials include acetophenone, benzophenone, benzylacetone, 1,3-diphenylacetone, cyclopentyl phenyl ketone, and the like.

In certain embodiments where the organic solvent includes a ketone, the ketone may be selected from acetone and acetophenone. One or more additional ketones and/or other organic solvents described herein may be provided, as well.

### Ethers:

In some embodiments, the organic solvent may be an ether having a formula of X—O—Y or X—O—[C(R)₂]ₙ—O—Y, where:
n is an integer from 1 to 4;
each X and Y can be independently selected from —[C(R¹)₂]ₘ—C(R²)₃ or —R³ or —[C(R⁴)₂]ₚ—O—[C(R⁵)₂]ₘ—C(R⁶)₃, wherein each of R¹, R², R³, R⁴, R⁵, R⁶ and R is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10 and p is an integer from 1 to 10;
in which X and Y, taken together with the atom to which each are attached, can optionally form a cycloheteroaliphatic group.

In some embodiments, each R, R¹, R², R³, R⁴, R⁵ and R⁶ independently are selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the ether may further be substituted with one or more substituents, such as alkoxy, amide, amine, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X and Y are taken together with the atom to which each are attached in order form a cycloheteroaliphatic group, the organic solvent is a cyclic ether, such as, acetal, dioxane, dioxolane, etc. In some embodiments, when n=1 and each R═H, X and Y taken together form a six, seven, eight, nine, or ten-membered ring. Example ethers include, but are not limited to, 1,3-dioxolane, or derivatives thereof. In other embodiments, when n=2 and R═H, X and Y form a seven, eight, nine, or ten-membered ring. Example ethers include, but are not limited to, 1,4-dioxane, or derivatives thereof. In yet other embodiments, when n=1 or n=2, then R is aliphatic, haloaliphatic, haloheteroaliphatic, heteroaliphatic, aromatic, aliphatic-aromatic, heteroaliphatic-aromatic, or any combinations thereof. Example cyclic ethers include tetrahydrofuran, 2-methyltetrahydrofuran, 2-methyl-1,3-dioxolane, and the like.

In other embodiments, when at least one of X or Y=aromatic, the organic solvent can be an aromatic ether. Example aromatic ethers include anisole, diphenyl ether, and the like.

In some embodiments, when at least one of X or Y=cycloaliphatic, the organic solvent can be a cycloalkyl ether. Example cycloalkyl ethers include cyclopentyl methyl ether, cyclohexyl methyl ether, and the like.

In other embodiments, when at least one of X or Y=—[C(R⁴)₂—O]ₚ—C(R⁶)₃, the organic solvent can be a glycol based ether. Example glycol based ethers include diethylene glycol diethyl ether, dipropylene glycol dimethyl ether, poly(ethylene glycol) dimethyl ether, etc., including methyl, ethyl, propyl, and butyl mono- and di-ethers of ethylene glycol, and the like.

### Nitriles:

In some cases, the organic solvent is a nitrile having a formula R—C≡N, where
R is aliphatic, haloaliphatic, haloheteroaliphatic, heteroaliphatic, aromatic, aliphatic-aromatic, or heteroaliphatic-aromatic.

In certain embodiments, R can be optionally substituted with a hydroxyl group (e.g., in one example R can be CH₃—CH(OH)—CH₂—, and the organic solvent will be CH₃—CH(OH)—CH₂—CN).

One example nitrile is acetonitrile, mentioned above.

In some embodiments, the organic solvent may include two or more of the organic solvents or types of organic solvents described herein. In some embodiments, water may be provided instead of, or in addition to, the organic solvent.

### Carrier Gas

The carrier gas may be an inert gas. In some cases the carrier gas is a noble gas. In certain embodiments, the carrier gas may be selected from the group consisting of N₂, He, Ne, Ar, Kr, and Xe. In some such embodiments, the carrier gas may be selected from the group consisting of N₂, He, and Ar.

### Additive

The additive may be selected from a number of different types of additives. For instance, in some cases the additive may be a heterocycle compound, a heterocyclic aromatic compound, a halogen-substituted heterocyclic aromatic compound, a heterocyclic aliphatic compound, an amine, a fluoroamine, an amino acid, an organophosphorus compound, an oxidizer, a bifluoride source, ammonia, an aldehyde, a carbene, or an organic acid. In some cases, more than one additive may be used. In some embodiments, the additive may be a boron-containing Lewis acid or Lewis adduct. Boron trifluoride (BF₃) is an example of a Lewis acid that forms the acid-base adduct BF₄⁻. In some cases, the additive may fall into two or more of the categories listed above. In various embodiments, the additive serves the purposes of accelerating the reaction rate and enhancing the reaction selectivity.

### Heterocyclic Aromatic Compounds:

In certain embodiments, the additive is a heterocyclic aromatic compound. The term “aromatic” is defined above. A heterocyclic aromatic compound is an aromatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aromatic compounds that may be used include, but are not limited to, a picoline, pyridine, pyrrole, imidazole, thiophene, N-methylimidazole, N-methylpyrrolidone, benzimidazole, 2,2-bipyridine, dipicolonic acid, 2,6-lutidine, 4-N,N-dimethylaminopyridine, and azulene. In some cases, a heterocyclic aromatic compound may be methylated. In some cases, a heterocyclic aromatic compound may follow the Hückel 4n+2 rule. In some cases, the additive is a halogen-substituted aromatic compound. A halogen-substituted aromatic compound is an aromatic compound that includes at least one halogen bonded to the aromatic ring. As used herein, halogen or halo refers to F, Cl, Br, or I. Example halogen-substituted aromatic compounds include, but are not limited to, 4-bromopyridine, chlorobenzene, 4-chlorotoluene, fluorobenzene, etc.

### Heterocyclic Aliphatic Compounds:

In some embodiments, the additive is a heterocyclic aliphatic compound. As used herein, “aliphatic” means a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well. A heterocyclic aliphatic compound is an aliphatic compound that includes a 5-, 6- or 7-membered ring, unless otherwise specified, containing one, two, three, or four non-carbon heteroatoms (e.g., independently selected from the group consisting of nitrogen, oxygen, phosphorous, sulfur, or halo). Example heterocyclic aliphatic compounds include pyrrolidine, piperidine, etc.

### Amines:

In some embodiments, the additive is an amine having a formula of NR¹R²R³, where:
each of R¹, R², and R³ is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof;
in which R¹ and R², taken together with the atom to which each are attached, can optionally form a cycloheteroaliphatic; and
in which R¹, R², and R³, taken together with the atom to which each are attached, can optionally form a cycloheteroaliphatic.

In some embodiments, each of R¹, R², and R³ is independently selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the amine may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when at least one of R¹, R², and R³ is aliphatic, haloaliphatic, haloheteroaliphatic, or heteroaliphatic, the additive is an alkyl amine. The alkyl amine can include dialkylamines, trialkyl amines, and derivatives thereof. Example alkyl amines include dimethylisopropylamine, N-ethyldiisopropylamine, trimethylamine, dimethylamine, methylamine, triethylamine, t-butyl amine, and the like.

In other embodiments, when at least one of R¹, R², and R³ includes a hydroxyl, the additive is an alcohol amine. In one instance, at least one of R¹, R², and R³ is an aliphatic group substituted with one or more hydroxyls. Example alcohol amines include 2-(dimethylamino) ethanol, 2-(diethylamino) ethanol, 2-(dipropylamino) ethanol, 2-(dibutylamino) ethanol, N-ethyldiethanolamine, N-tertbutyldiethanolamine, and the like.

In some embodiments, when R¹ and R², taken together with the atom to which each are attached, form a cycloheteroaliphatic, the additive can be a cyclic amine. Example cyclic amines include piperidine, N-alkyl piperidine (e.g., N-methyl piperidine, N-propyl piperidine, etc.), pyrrolidine, N-alkyl pyrrolidine (e.g., N-methyl pyrrolidine, N-propyl pyrrolidine, etc.), morpholine, N-alkyl morpholine (e.g., N-methyl morpholine, N-propyl morpholine, etc.), piperazine, N-alkyl piperazine, N,N-dialkyl piperazine (e.g., 1,4-dimethylpiperazine), and the like.

In other embodiments, when at least one of R¹, R², and R³ includes an aromatic, the additive is an aromatic amine. In some embodiments, at least one of R¹, R², and R³ is aromatic, aliphatic-aromatic, or heteroaliphatic-aromatic. In other embodiments, both R¹ and R² includes an aromatic. In yet other embodiments, R¹ and R² and optionally R³, taken together with the atom to which each are attached, from a cycloheteroaliphatic that is an aromatic. Example aromatic amines include aniline, histamine, pyrrole, pyridine, imidazole, pyrimidine, and the derivatives thereof.

In some embodiments, the additive may include an amine selected from the group consisting of: methylamine, dimethylamine, trimethylamine, ethylamine, diethylamine, triethylamine, isopropylamine, 1,2-ethylenediamine, aniline (and aniline derivatives such as N,Ndimethylaniline), N-ethyldiisopropylamine, tert-butylamine, and combinations thereof.

In some embodiments, the additive may include a fluoramine. A fluoramine is an amine having one or more fluorinated substituents. Example fluoroamines that may be used include, but are not limited to, 4-trifluoromethylaniline.

In some embodiments, the additive can be a nitrogenous analogue of a carbonic acid, having a formula R¹N—C(NR²)—NR³. Example additives can include, but are not limited to, guanidine or derivatives thereof.

In some embodiments, the additive may be a relatively low molecular weight amine, e.g., having a molecular weight of less than 200 g/mol or 100 g/mol in certain embodiments. Higher molecular weight amines, including those having long chains and/or heterocyclic compounds with aromatic rings, may be used in some embodiments.

### Amino Acids:

In some embodiments, the additive may include an amino acid. The amino acid may have a formula of R—CH(NR′₂)—COOH, where:
each R and R′ independently are hydroxyl, aliphatic, haloaliphatic, haloheteroaliphatic, heteroaliphatic, aromatic, aliphatic-aromatic, heteroaliphatic-aromatic, or any combination thereof.

Example amino acids that may be used include, but are not limited to, histidine, alanine, and derivatives thereof.

### Organophosphorus Compounds:

In some embodiments, the additive may include an organophosphorus compound. The organophosphorus compound may be a phosphate ester, a phosphate amide, a phosphonic acid, a phosphinic acid, a phosphonate, a phosphinate, a phosphine oxide, a phosphine imide, or a phosphonium salt. Example organophosphorus compounds include phosphoric acid and trialkylphosphate. In some cases, the organophosphorous compound is a phosphazene. A phosphazene is an organophosphorus compound that includes phosphorus (V) with a double bond between P and N. The phosphazene may have a formula of RN═P(NR₂)₃ (where each of R and R₂ are independently selected from hydroxyl, aliphatic, haloaliphatic, haloheteroaliphatic, heteroaliphatic, aromatic, aliphatic-aromatic, heteroaliphatic-aromatic, or any combination thereof). In some cases, the phosphazene may have a formula of [X₂PN]ₙ (where X is a halide, alkoxide, or amide). Other types of phosphazenes may be used as desired.

### Oxidizers:

In some embodiments, the additive includes an oxidizer. As used herein, an oxidizer is a material that has the ability to oxidize (e.g., accept electrons from) another substance. Example oxidizers that may be used include, but are not limited to, hydrogen peroxide, sodium hypochlorate, and tetramethyl ammonium hydroxide.

### Bifluoride Sources:

In some embodiments, the additive includes a bifluoride source. A bifluoride source is a material that includes or produces bifluoride (HF₂⁻). Example bifluoride sources that may be used include, but are not limited to, ammonium fluoride, aqueous HF, gaseous HF, buffered oxide etch mixture (e.g., a mixture of HF and a buffering agent such as ammonium fluoride), and hydrogen fluoride pyridine. In some embodiments, the bifluoride source (and/or one or more of the other additives listed herein) may react to form HF₂⁻ before or after delivery to the reaction chamber.

### Aldehydes:

In some embodiments, the additive includes an aldehyde having a formula of X—[C(O)]—H, where:
X can be selected from hydrogen, —R¹, —C(R²)₃ or —[C(R³)₂]ₘ—C(O)H, wherein each R¹, R² and R³ independently are selected from hydrogen, aliphatic, haloaliphatic, haloheteroaliphatic, heteroaliphatic, aromatic, aliphatic-aromatic, heteroaliphatic-aromatic, or any combinations thereof, and m is an integer from 0 to 10.

In some embodiments, each of R¹, R², and R³ is, independently, alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the aldehyde or ketone may further be substituted with one or more substituents, such as aldehyde (—C(O)H), oxo (═O), alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof.

In some embodiments, when X=aromatic, the additive can be an aromatic aldehyde. Example aromatic aldehydes include benzaldehyde, 1-naphthaldehyde, phthalaldehyde, and the like.

In other embodiments, when X=aliphatic, the additive can be an aliphatic aldehyde. Example aliphatic aldehydes include acetaldehyde, propionaldehyde, butyraldehyde, isovalerylaldehyde, and the like.

In yet other embodiments, when X=—[C(R³)₂]ₘ—C(O)H and m is 0 to 10 or when X=aliphatic or heteroaliphatic substituted with —C(O)H, the additive can be a dialdehyde. Example dialdehydes include glyoxal, phthalaldehyde, glutaraldehyde, malondialdehyde, succinaldehyde, and the like.

In some examples, an aldehyde used as an additive may be selected from the group consisting of: acrolein, acetaldehyde, formaldehyde, benzaldehyde, propionaldehyde, butyraldehyde, cinnamaldehyde, vanillin, and tolualdehyde. In these or other cases, an aldehyde used as an additive may be selected from the aldehydes discussed in this section and the aldehydes discussed in the organic solvent section.

### Carbenes:

In some embodiments, the additive includes a carbene. The carbene may have a formula of X—(C:)—Y, where:
each of X and Y can be independently selected from H, halo, —[C(R¹)₂]ₘ—C(R²)₃, —C(O)—R¹, or —C(═NR¹)—R², —NR¹R², —OR², —SR², or —C(R²)₃, wherein each of R¹ and R² is independently selected from hydrogen, hydroxyl, aliphatic, haloaliphatic, haloheteroaliphatic, heteroaliphatic, aromatic, aliphatic-aromatic, heteroaliphatic-aromatic, or any combinations thereof, and wherein m is an integer from 0 to 10;
in which R¹ and R², taken together with the atom to which each are attached, can optionally form a cycloheteroaliphatic group; and
in which X and Y, taken together with the atom to which each are attached, can optionally form a cycloaliphatic or cycloheteroaliphatic group.

Furthermore, the additive can be a carbenium cation having a formula R¹—C⁺(R)—R², wherein each of R, R¹, and R² is independently selected from hydrogen, aliphatic, haloaliphatic, haloheteroaliphatic, heteroaliphatic, aromatic, aliphatic-aromatic, heteroaliphatic-aromatic, or any combinations thereof.

In some embodiments, each R, R¹, and R² independently is selected from alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heterocyclyl, heteroaryl, alkyl-aryl, alkenyl-aryl, alkynyl-aryl, alkyl-heterocyclyl, alkenyl-heterocyclyl, alkynyl-heterocyclyl, alkyl-heteroaryl, alkenyl-heteroaryl, alkynyl-heteroaryl, heteroalkyl-aryl, heteroalkenyl-aryl, heteroalkynyl-aryl, heteroalkyl-heterocyclyl, heteroalkenyl-heterocyclyl, heteroalkynyl-heterocyclyl, heteroalkyl-heteroaryl, heteroalkenyl-heteroaryl, heteroalkynyl-heteroaryl, or any combinations thereof. In particular disclosed embodiments, the carbene may further be substituted with one or more substituents, such as alkoxy, amide, amine, hydroxyl, thioether, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide, or any combinations thereof. In any embodiment of a carbene, each of R¹ and R² can be independently selected.

In some embodiments, when at least one of X or Y is halo, the additive can be a halocarbene. Example, non-limiting halocarbenes include dihalocarbene, such as dichlorocarbene, difluorocarbene, and the like.

In some embodiments, when both X=Y=—NR¹R², the additive can be a diaminocarbene. In one instance, each of R¹ and R² is independently aliphatic. Example diaminocarbenes include bis(diisopropylamino) carbene, and the like.

In other embodiments, when both at least one of X or Y=—NR¹R² and both R¹ and R² within X or within Y are taken together, with the nitrogen atom to which each are attached, to form a cycloheteroaliphatic group, the additive can be a cyclic diaminocarbene. Example cyclic diamino carbenes include bis(N-piperidyl) carbene, bis(N-pyrrolidinyl) carbene, and the like.

In one instance, when both X=Y=—NR¹R² and an R¹ group from X and an R² group from Y are taken together, with the nitrogen atom to which each are attached, to form a cycloheteroaliphatic group, the additive is an N-heterocyclic carbene. Example N-heterocyclic carbenes include imidazol-2-ylidenes (e.g., 1,3-dimesitylimidazol-2-ylidene, 1,3-dimesityl-4,5-dichloroimidazol-2-ylidene, 1,3-bis(2,6-diisopropylphenyl)imidazol-2-ylidene, 1,3-di-tert-butylimidazol-2-ylidene, etc.), imidazolidin-2-ylidenes (e.g., 1,3-bis(2,6-diisopropylphenyl)imidazolidin-2-ylidene), triazol-5-ylidenes (e.g., 1,3,4-triphenyl-4,5-dihydro-1H-1,2,4-triazol-5-ylidene), and the like.

In some embodiments, when X=—NR¹R² and Y=—SR² and an R¹ group from X and an R² group from Y are taken together, with the nitrogen atom to which each are attached, to form a cycloheteroaliphatic group, the additive is acyclic thioalkyl amino carbene. Example cyclic thioalkyl amino carbenes include thiazol-2-ylidenes (e.g., 3-(2,6-diisopropylphenyl)thiazol-2-ylidene and the like).

In some embodiments, when X=—NR¹R² and Y=—C(R²)₃ and an R¹ group from X and an R² group from Y are taken together, with the atom to which each are attached, to form a cycloheteroaliphatic group, the additive is an cyclic alkyl amino carbene.

Example cyclic alkyl amino carbenes include pyrrolidine-2-ylidenes (e.g., 1,3,3,5,5-pentamethyl-pyrrolidin-2-ylidene and the like) and piperidin-2-ylidenes (e.g., 1,3,3,6,6-pentamethyl-piperidin-2-ylidene and the like).

Further example carbenes and derivatives thereof include compounds having a thiazol-2-ylidene moiety, a dihydroimidazol-2-ylidene moiety, an imidazol-2-ylidene moiety, a triazol-5-ylidene moiety, or a cyclopropenylidene moiety. Yet other carbenes and carbene analogs include an aminothiocarbene compound, an aminooxycarbene compound, a diaminocarbene compound, a heteroamino carbene compound, a 1,3-dithiolium carbene compound, a mesoionic carbene compound (e.g., an imidazolin-4-ylidene compound, a 1,2,3-triazolylidene compound, a pyrazolinylidene compound, a tetrazol-5-ylidene compound, an isoxazol-4-ylidene compound, a thiazol-5-ylidene compound, etc.), a cyclic alkyl amino carbene compound, a boranylidene compound, a silylene compound, a stannylene compound, a nitrene compound, a phosphinidene compound, a foiled carbene compound, etc. Further example carbenes include dimethyl imidazol-2-ylidene, 1,3-bis(2,4,6-trimethylphenyl)-4,5-dihydroimidazol-2-ylidene, (phosphanyl)(trifluoromethyl)carbene, bis(diisopropylamino) carbene, bis(diisopropylamino) cyclopropenylidene, 1,3-dimesityl-4,5-dichloroimidazol-2-ylidene, 1,3-diadamantylimidazol-2-ylidene, 1,3,4,5-tetramethylimidazol-2-ylidene, 1,3-dimesitylimidazol-2-ylidene, 1,3-dimesitylimidazol-2-ylidene, 1,3,5-triphenyltriazol-5-ylidene, bis(diisopropylamino) cyclopropenylidene, bis(9-anthryl)carbene, norbornen-7-ylidene, dihydroimidazol-2-ylidene, methylidenecarbene, etc.

### Organic Acids:

In some embodiments, the additive includes an organic acid. The organic acid may have a formula of R—CO²H, wherein R is selected from hydrogen, aliphatic, haloaliphatic, haloheteroaliphatic, heteroaliphatic, aromatic, aliphatic-aromatic, heteroaliphatic-aromatic or any combinations thereof. In certain embodiments, R is alkyl, alkenyl, alkynyl, heteroalkyl, heteroalkenyl, heteroalkynyl, haloalkyl, haloalkenyl, haloalkynyl, haloheteroalkyl, haloheteroalkenyl, haloheteroalkynyl, aryl, heteroaryl, alkyl-aryl, alkenyl-aryl, alkynyl-aryl, alkyl-heteroaryl, alkenyl-heteroaryl, alkynyl-heteroaryl, heteroalkyl-aryl, heteroalkenyl-aryl, heteroalkynyl-aryl, heteroalkyl-heteroaryl, heteroalkenyl-heteroaryl, heteroalkynyl-heteroaryl or any combinations thereof. In particular disclosed embodiments, R may further be substituted with one or more substituents such as, alkoxy, amide, amine, thioether, hydroxyl, thiol, acyloxy, silyl, cycloaliphatic, aryl, aldehyde, ketone, ester, carboxylic acid, acyl, acyl halide, cyano, halogen, sulfonate, nitro, nitroso, quaternary amine, pyridinyl (or pyridinyl wherein the nitrogen atom is functionalized with an aliphatic or aryl group), alkyl halide or any combinations thereof. In certain implementations, the organic acid may be selected from formic acid and acetic acid.

### Substitutions:

Any of the example materials described herein include unsubstituted and/or substituted forms of the compound. Non-limiting example substituents include, e.g., one, two, three, four, or more substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (5) aryl; (6) arylalkoxy (e.g.,—O-L-R, in which L is alkyl and R is aryl); (7) aryloyl (e.g., —C(O)—R, in which R is aryl); (8) azido (e.g., —N₃); (9) cyano (e.g.,—CN); (10) aldehyde (e.g., —C(O)H); (11) C₃₋₈ cycloalkyl; (12) halo; (13) heterocyclyl (e.g., as defined herein, such as a 5- , 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkoxy (e.g., —S—R, in which R is C₁₋₆ alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g.,-L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g.,-L-R, in which L is C₁₋₆ alkyl and R is C₄₋₁₈ aryl); (24) —SO₂R¹, where R¹ is selected from the group consisting of (a) C₁₋₆ alkyl, (b) C₄₋₁₈ aryl, and (c) C₁₋₆ alkyl-C₄₋₁₈ aryl (e.g.,-L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g.,-L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g.,-L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g.,-L-R, in which L is C₁₋₆ alkyl and R is C₃₋₈ cycloalkyl), wherein in one embodiment no two groups are bound to the nitrogen atom through a carbonyl group or a sulfonyl group.

In certain embodiments, the additive may act as a proton acceptor and promote formation of HF₂⁻. In some such cases, the HF₂⁻ may actively etch one or more materials on the substrate such as an oxide material or another material.

### Etching

The vapor phase species delivered to the reaction chamber may be collectively referred to as a gas mixture. The non-inert species delivered to the reaction chamber (e.g., the reactants other than the carrier gas) may be collectively referred to as a reactant mixture. The gas mixture includes the reactant mixture and the carrier gas. In some cases, the reactant mixture and/or the gas mixture may have a particular composition. For example, halogen source may be provided in the reactant mixture at a concentration between about 20-100% (by volume), or between about 20-99% (by volume). In these or other cases, halogen source may be provided in the gas mixture at a concentration between about 0.5-20% (by volume). The organic solvent and/or water may be provided in the reactant mixture at a concentration between about 10-100% (by volume), or between about 10-99% (by volume). In these or other cases, the organic solvent and/or water may be provided in the gas mixture at a concentration between about 0-10% (by volume), such as between about 1-10% (by volume). The additive may be provided in the reactant mixture at a concentration of between about 0.2-5% (by volume). In these or other cases, the additive may be provided in the gas mixture at a concentration between about 0-0.2%, or between about 0.0001-0.2% (by volume). The carrier gas may be provided in the gas mixture at a concentration between about 0-99% (by volume).

In some embodiments, the additive and organic solvent and/or water are mixed such that the additive is between about 0.1-5% (by weight) of the additive/organic solvent and/or water mixture. A reactant mixture regardless of the order of mixing may be characterized by the additive being about 0.1-5% (by weight) of the total of the amounts of additive and organic solvent and/or water.

In the same or alternate embodiments, the reactant mixture may be characterized by halogen source:additive ratio (by volume). As described further below, in some embodiments, the selectivity can be tuned by the halogen source: additive vol. ratio, with selectivity increasing with an increasing amount of additive (and thus a decreasing ratio). In some embodiments, the halogen source:additive ratio is less than or equal to 10. In some embodiments, the halogen:source additive ratio is greater than 10.

According to various embodiments, the reactant mixture may include a halogen source, an alcohol, and an amine, where the amine is between 0.1-5% wt of the total alcohol and amine amounts. In some embodiments, the halogen source: amine volumetric ratio is no more than 10. In other embodiments, the halogen source:amine volumetric ratio is 10 or higher.

As described above, according to various implementations, the etch may be selective to one material on a substrate with respect to another material. In other implementations, the etch may be non-selective with respect to multiple materials on a substrate.

### Additional Definitions

This section presents additional definitions that may be used herein. Some of the materials described in this section may overlap with those presented elsewhere in the application.

The term “acyl,” or “alkanoyl,” as used interchangeably herein, represents groups of 1, 2, 3, 4, 5, 6, 7, 8 or more carbon atoms of a straight, branched, cyclic configuration, saturated, unsaturated and aromatic, and combinations thereof, or hydrogen, attached to the parent molecular group through a carbonyl group, as defined herein. This group is exemplified by formyl, acetyl, propionyl, isobutyryl, butanoyl, and the like. In some embodiments, the acyl or alkanoyl group is —C(O)—R, in which R is hydrogen, an aliphatic group, or an aromatic group, as defined herein.

By “acyl halide” is meant —C(O)X, where X is a halogen, such as Br, F, I, or Cl.

By “aldehyde” is meant a —C(O)H group.

By “aliphatic” is meant a hydrocarbon group having at least one carbon atom to 50 carbon atoms (C₁₋₅₀), such as one to 25 carbon atoms (C₁₋₂₅), or one to ten carbon atoms (C₁₋₁₀), and which includes alkanes (or alkyl), alkenes (or alkenyl), alkynes (or alkynyl), including cyclic versions thereof, and further including straight- and branched-chain arrangements, and all stereo and position isomers as well.

By “alkyl-aryl,” “alkenyl-aryl,” and “alkynyl-aryl” is meant an aryl group, as defined herein, that is or can be coupled (or attached) to the parent molecular group through an alkyl, alkenyl, or alkynyl group, respectively, as defined herein. The alkyl-aryl, alkenyl-aryl, and/or alkynyl-aryl group can be substituted or unsubstituted. For example, the alkyl-aryl, alkenyl-aryl, and/or alkynyl-aryl group can be substituted with one or more substitution groups, as described herein for alkyl, alkenyl, alkynyl, and/or aryl. Example unsubstituted alkyl-aryl groups are of from 7 to 16 carbons (C₇₋₁₆ alkyl-aryl), as well as those having an alkyl group with 1 to 6 carbons and an aryl group with 4 to 18 carbons (i.e., C₁₋₆ alkyl-C₄₋₁₈ aryl). Example unsubstituted alkenyl-aryl groups are of from 7 to 16 carbons (C₇₋₁₆ alkenyl-aryl), as well as those having an alkenyl group with 2 to 6 carbons and an aryl group with 4 to 18 carbons (i.e., C₂₋₆ alkenyl-C₄₋₁₈ aryl). Example unsubstituted alkynyl-aryl groups are of from 7 to 16 carbons (C₇₋₁₆ alkynyl-aryl), as well as those having an alkynyl group with 2 to 6 carbons and an aryl group with 4 to 18 carbons (i.e., C₂₋₆ alkynyl-C₄₋₁₈ aryl). In some embodiments, the alkyl-aryl group is-L-R, in which L is an alkyl group, as defined herein, and R is an aryl group, as defined herein. In some embodiments, the alkenyl-aryl group is-L-R, in which L is an alkenyl group, as defined herein, and R is an aryl group, as defined herein. In some embodiments, the alkynyl-aryl group is-L-R, in which L is an alkynyl group, as defined herein, and R is an aryl group, as defined herein.

By “alkenyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon double bond, wherein the unsaturated monovalent hydrocarbon can be derived from removing one hydrogen atom from one carbon atom of a parent alkene. An alkenyl group can be branched, straight-chain, cyclic (e.g., cycloalkenyl), cis, or trans (e.g., E or Z). An example alkenyl includes an optionally substituted C₂₋₂₄ alkyl group having one or more double bonds. The alkenyl group can be monovalent or multivalent (e.g., bivalent) by removing one or more hydrogens to form appropriate attachment to the parent molecular group or appropriate attachment between the parent molecular group and another substitution. The alkenyl group can also be substituted or unsubstituted. For example, the alkenyl group can be substituted with one or more substitution groups, as described herein for alkyl.

By “alkyl-heteroaryl” is meant a heteroaryl group, as defined herein, attached to the parent molecular group through an alkyl group, as defined herein. In some embodiments, the alkyl-heteroaryl group is-L-R, in which L is an alkyl group, as defined herein, and R is a heteroaryl group, as defined herein.

By “alkyl-heterocyclyl,” “alkenyl-heterocyclyl,” and “alkynyl-heterocyclyl” is meant a heterocyclyl group, as defined herein, that is or can be coupled (or attached) to the parent molecular group through an alkyl, alkenyl, or alkynyl group, respectively, as defined herein. The alkyl-heterocyclyl, alkenyl-heterocyclyl, and/or alkynyl-heterocyclyl group can be substituted or unsubstituted. For example, the alkyl-heterocyclyl, alkenyl-heterocyclyl, and/or alkynyl-heterocyclyl group can be substituted with one or more substitution groups, as described herein for alkyl, alkenyl, alkynyl, and/or heterocyclyl. Example unsubstituted alkyl-heterocyclyl groups are of from 2 to 16 carbons (C₂₋₁₆ alkyl-heterocyclyl), as well as those having an alkyl group with 1 to 6 carbons and a heterocyclyl group with 1 to 18 carbons (i.e., C₁₋₆ alkyl-C₁₋₁₈ heterocyclyl). Example unsubstituted alkenyl-heterocyclyl groups are of from 3 to 16 carbons (C₃₋₁₆ alkenyl-heterocyclyl), as well as those having an alkenyl group with 2 to 6 carbons and a heterocyclyl group with 1 to 18 carbons (i.e., C₂₋₆ alkenyl-C₁₋₁₈ heterocyclyl). Example unsubstituted alkynyl-heterocyclyl groups are of from 3 to 16 carbons (C₃₋₁₆ alkynyl-heterocyclyl), as well as those having an alkynyl group with 2 to 6 carbons and a heterocyclyl group with 1 to 18 carbons (i.e., C₂₋₆ alkynyl-C₁₋₁₈ heterocyclyl). In some embodiments, the alkyl-heterocyclyl group is-L-R, in which L is an alkyl group, as defined herein, and R is a heterocyclyl group, as defined herein. In some embodiments, the alkenyl-heterocyclyl group is-L-R, in which L is an alkenyl group, as defined herein, and R is a heterocyclyl group, as defined herein. In some embodiments, the alkynyl-heterocyclyl group is-L-R, in which L is an alkynyl group, as defined herein, and R is a heterocyclyl group, as defined herein.

By “alkoxy” is meant —OR, where R is an optionally substituted aliphatic group, as described herein. Example alkoxy groups include, but are not limited to, methoxy, ethoxy, n-propoxy, isopropoxy, n-butoxy, t-butoxy, sec-butoxy, n-pentoxy, trihaloalkoxy, such as trifluoromethoxy, etc. The alkoxy group can be substituted or unsubstituted. For example, the alkoxy group can be substituted with one or more substitution groups, as described herein for alkyl. Example unsubstituted alkoxy groups include C₁₋₃, C₁₋₆, C₁₋₁₂, C₁₋₁₆, C₁₋₁₈, C₁₋₂₀, or C₁₋₂₄ alkoxy groups.

By “alkyl” is meant a saturated monovalent hydrocarbon having at least one carbon atom to 50 carbon atoms (C₁₋₅₀), such as one to 25 carbon atoms (C₁₋₂₅), or one to ten carbon atoms (C₁₋₁₀), wherein the saturated monovalent hydrocarbon can be derived from removing one hydrogen atom from one carbon atom of a parent compound (e.g., alkane). An alkyl group can be branched, straight-chain, or cyclic (e.g., cycloalkyl). An example alkyl includes a branched or unbranched saturated hydrocarbon group of 1 to 24 carbon atoms, such as methyl, ethyl, n-propyl, isopropyl, n-butyl, isobutyl, s-butyl, t-butyl, n-pentyl, isopentyl, s-pentyl, neopentyl, hexyl, heptyl, octyl, nonyl, decyl, dodecyl, tetradecyl, hexadecyl, eicosyl, tetracosyl, and the like. The alkyl group can also be substituted or unsubstituted. The alkyl group can be monovalent or multivalent (e.g., bivalent) by removing one or more hydrogens to form appropriate attachment to the parent molecular group or appropriate attachment between the parent molecular group and another substitution. For example, the alkyl group can be substituted with one, two, three or, in the case of alkyl groups of two carbons or more, four substituents independently selected from the group consisting of: (1) C₁₋₆ alkoxy (e.g., —O—R, in which R is C₁₋₆ alkyl); (2) C₁₋₆ alkylsulfinyl (e.g., —S(O)—R, in which R is C₁₋₆ alkyl); (3) C₁₋₆ alkylsulfonyl (e.g., —SO₂—R, in which R is C₁₋₆ alkyl); (4) amine (e.g., —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (5) aryl; (6) arylalkoxy (e.g., —O-L-R, in which L is alkyl and R is aryl); (7) aryloyl (e.g., —C(O)—R, in which R is aryl); (8) azido (e.g., —N₃); (9) cyano (e.g., —CN); (10) aldehyde (e.g., —C(O)H); (11) C₃₋₈ cycloalkyl; (12) halo; (13) heterocyclyl (e.g., as defined herein, such as a 5- , 6- or 7-membered ring containing one, two, three, or four non-carbon heteroatoms); (14) heterocyclyloxy (e.g., —O—R, in which R is heterocyclyl, as defined herein); (15) heterocyclyloyl (e.g., —C(O)—R, in which R is heterocyclyl, as defined herein); (16) hydroxyl (e.g., —OH); (17) N-protected amino; (18) nitro (e.g., —NO₂); (19) oxo (e.g., ═O); (20) C₁₋₆ thioalkoxy (e.g., —S—R, in which R is alkyl); (21) thiol (e.g., —SH); (22) —CO₂R¹, where R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g.,-L-R, in which L is C₁₋₆ alkyl and R is C₄₋₁₈ aryl); (23) —C(O)NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g.,-L-R, in which L is C₁₋₆ alkyl and R is C₄₋₁₈ aryl); (24) —SO₂R₁, where R₁ is selected from the group consisting of (a) C₁₋₆ alkyl, (b) C₄₋₁₈ aryl, and (c) C₁₋₆ alkyl-C₄₋₁₈ aryl (e.g.,-L-R, in which L is C₁₋₆ alkyl and R is C₄₋₁₈ aryl); (25) —SO₂NR¹R², where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g., -L-R, in which L is C₁₋₆ alkyl and R is C₄₋₁₈ aryl); and (26) —NR¹R², where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g.,-L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g.,-L-R, in which L is C₁₋₆ alkyl and R is C₃₋₈ cycloalkyl), wherein in one embodiment no two groups are bound to the nitrogen atom through a carbonyl group or a sulfonyl group. The alkyl group can be a primary, secondary, or tertiary alkyl group substituted with one or more substituents (e.g., one or more halo or alkoxy). In some embodiments, the unsubstituted alkyl group is a C₁₋₃, C₁₋₆, C₁₋₁₂, C₁₋₁₆, C₁₋₁₈, C₁₋₂₀, or C₁₋₂₄ alkyl group.

By “alkylsulfinyl” is meant an alkyl group, as defined herein, attached to the parent molecular group through an —S(O)-group. In some embodiments, the unsubstituted alkylsulfinyl group is a C₁₋₆ or C₁₋₁₂ alkylsulfinyl group. In other embodiments, the alkylsulfinyl group is —S(O)-R, in which R is an alkyl group, as defined herein.

By “alkylsulfonyl” is meant an alkyl group, as defined herein, attached to the parent molecular group through an —SO₂-group. In some embodiments, the unsubstituted alkylsulfonyl group is a C₁₋₆ or C₁₋₁₂ alkylsulfonyl group. In other embodiments, the alkylsulfonyl group is —SO₂-R, where R is an optionally substituted alkyl (e.g., as described herein, including optionally substituted C₁₋₁₂ alkyl, haloalkyl, or perfluoroalkyl).

By “alkynyl” is meant an unsaturated monovalent hydrocarbon having at least two carbon atom to 50 carbon atoms (C₂₋₅₀), such as two to 25 carbon atoms (C₂₋₂₅), or two to ten carbon atoms (C₂₋₁₀), and at least one carbon-carbon triple bond, wherein the unsaturated monovalent hydrocarbon can be derived from removing one hydrogen atom from one carbon atom of a parent alkyne. An alkynyl group can be branched, straight-chain, or cyclic (e.g., cycloalkynyl). An example alkynyl includes an optionally substituted C₂₋₂₄ alkyl group having one or more triple bonds. The alkynyl group can be cyclic or acyclic and is exemplified by ethynyl, 1-propynyl, and the like. The alkynyl group can be monovalent or multivalent (e.g., bivalent) by removing one or more hydrogens to form appropriate attachment to the parent molecular group or appropriate attachment between the parent molecular group and another substitution. The alkynyl group can also be substituted or unsubstituted. For example, the alkynyl group can be substituted with one or more substitution groups, as described herein for alkyl.

By “amide” is mean —C(O)NR¹R² or —NHCOR¹, where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein.

By “amine” is meant —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein.

By “aminoalkyl” is meant an alkyl group, as defined herein, substituted by an amine group, as defined herein. In some embodiments, the aminoalkyl group is-L-NR¹R², in which L is an alkyl group, as defined herein, and each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein. In other embodiments, the aminoalkyl group is-L-C(NR¹R²)(R³)—R⁴, in which L is a covalent bond or an alkyl group, as defined herein; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein; and each of R³ and R⁴ is, independently, H or alkyl, as defined herein.

By “aromatic” is meant a cyclic, conjugated group or moiety of, unless specified otherwise, from 5 to 15 ring atoms having a single ring (e.g., phenyl) or multiple condensed rings in which at least one ring is aromatic (e.g., naphthyl, indolyl, or pyrazolopyridinyl); that is, at least one ring, and optionally multiple condensed rings, have a continuous, delocalized π-electron system. Typically, the number of out of plane π-electrons corresponds to the Huckel rule (4n+2). The point of attachment to the parent structure typically is through an aromatic portion of the condensed ring system.

By “aryl” is meant an aromatic carbocyclic group comprising at least five carbon atoms to 15 carbon atoms (C₅₋₁₅), such as five to ten carbon atoms (C₅₋₁₀), having a single ring or multiple condensed rings, which condensed rings can or may not be aromatic provided that the point of attachment to a remaining position of the compounds disclosed herein is through an atom of the aromatic carbocyclic group. Aryl groups may be substituted with one or more groups other than hydrogen, such as aliphatic, heteroaliphatic, aromatic, other functional groups, or any combination thereof. Example aryl groups include, but are not limited to, benzyl, naphthalene, phenyl, biphenyl, phenoxybenzene, and the like. The term aryl also includes heteroaryl, which is defined as a group that contains an aromatic group that has at least one heteroatom incorporated within the ring of the aromatic group. Examples of heteroatoms include, but are not limited to, nitrogen, oxygen, sulfur, and phosphorus. Likewise, the term non-heteroaryl, which is also included in the term aryl, defines a group that contains an aromatic group that does not contain a heteroatom. The aryl group can be substituted or unsubstituted. The aryl group can be substituted with one, two, three, four, or five substituents independently selected from the group consisting of: (1) C₁₋₆ alkanoyl (e.g., —C(O)—R, in which R is C₁₋₆ alkyl); (2) C₁₋₆ alkyl; (3) C₁₋₆ alkoxy (e.g., —O—R, in which R is C₁₋₆ alkyl); (4) C₁₋₆ alkoxy-C₁₋₆ alkyl (e.g.,-L-O—R, in which each of L and R is, independently, C₁₋₆ alkyl); (5) C₁₋₆ alkylsulfinyl (e.g., —S(O)—R, in which R is C₁₋₆ alkyl); (6) C₁₋₆ alkylsulfinyl-C₁₋₆ alkyl (e.g.,-L-S(O)—R, in which each of L and R is, independently, C₁₋₆ alkyl); (7) C₁₋₆ alkylsulfonyl (e.g., —SO₂—R, in which R is C₁₋₆ alkyl); (8) C₁₋₆ alkylsulfonyl-C₁₋₆ alkyl (e.g.,-L-SO₂—R, in which each of L and R is, independently, C₁₋₆ alkyl); (9) aryl; (10) amine (e.g., —NR¹R², where each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein); (11) C₁₋₆ aminoalkyl (e.g.,-L¹-NR¹R² or-L²-C(NR¹R²)(R³)—R⁴, in which L¹ is C₁₋₆ alkyl; L2 is a covalent bond or C₁₋₆ alkyl; each of R¹ and R² is, independently, selected from hydrogen, aliphatic, heteroaliphatic, haloaliphatic, haloheteroaliphatic, aromatic, as defined herein, or any combination thereof, or R¹ and R², taken together with the nitrogen atom to which each are attached, form a heterocyclyl group, as defined herein; and each of R³ and R⁴ is, independently, H or C₁₋₆ alkyl); (12) heteroaryl; (13) C₁₋₆ alkyl-C₄₋₁₈ aryl (e.g.,-L-R, in which L is C₁₋₆ alkyl and R is C₄₋₁₈ aryl); (14) aryloyl (e.g., —C(O)—R, in which R is aryl); (15) azido (e.g., —N₃); (16) cyano (e.g., —CN); (17) C₁₋₆ azidoalkyl (e.g.,-L-N₃, in which L is C₁₋₆ alkyl); (18) aldehyde (e.g., —C(O)H); (19) aldehyde-C₁₋₆ alkyl (e.g.,-L-C(O)H, in which L is C₁₋₆ alkyl); (20) C₃₋₈ cycloalkyl; (21) C₁₋₆ alkyl-C₃₋₈ cycloalkyl (e.g.,-L-R, in which L is C₁₋₆ alkyl and R is C₃₋₈ cycloalkyl); (22) halo; (23) C₁₋₆ haloalkyl (e.g.,-L¹-X or-L²-C(X)(R¹)—R², in which L¹ is C₁₋₆ alkyl; L² is a covalent bond or C₁₋₆ alkyl; X is fluoro, bromo, chloro, or iodo; and each of R¹ and R² is, independently, H or C₁₋₆ alkyl); (24) heterocyclyl (e.g., as defined herein, such as a 5- , 6- or 7-membered ring containing one, two, three, or four non-carbon heteroatoms); (25) heterocyclyloxy (e.g., —O—R, in which R is heterocyclyl, as defined herein); (26) heterocyclyloyl (e.g., —C(O)—R, in which R is heterocyclyl, as defined herein); (27) hydroxyl (—OH); (28) C₁₋₆ hydroxyalkyl (e.g.,-L¹-OH or-L²-C(OH)(R¹)—R², in which L¹ is C₁₋₆ alkyl; L² is a covalent bond or alkyl; and each of R¹ and R² is, independently, H or C₁₋₆ alkyl, as defined herein); (29) nitro; (30) C₁₋₆ nitroalkyl (e.g.,-L¹-NO or-L²-C(NO)(R¹)—R², in which L¹ is C₁₋₆ alkyl; L² is a covalent bond or alkyl; and each of R¹ and R² is, independently, H or C₁₋₆ alkyl, as defined herein); (31) N-protected amino; (32) N-protected amino-C₁₋₆ alkyl; (33) oxo (e.g., ═O); (34) C₁₋₆ thioalkoxy (e.g., —S—R, in which R is C₁₋₆ alkyl); (35) thio-C₁₋₆ alkoxy-C₁₋₆ alkyl (e.g.,-L-S—R, in which each of L and R is, independently, C₁₋₆ alkyl); (36) —(CH₂)ᵣCO₂R¹, where r is an integer of from zero to four, and R¹ is selected from the group consisting of (a) hydrogen, (b) C₁₋₆ alkyl, (c) C₄₋₁₈ aryl, and (d) C₁₋₆ alkyl-C₄₋₁₈ aryl (e.g.,-L-R, in which L is C₁₋₆ alkyl and R is C₄₋₁₈ aryl); (37) —(CH₂)ᵣCONR¹R², where r is an integer of from zero to four and where each R¹ and R² is independently selected from the group consisting of (a) hydrogen, (b) C₁₋₆ alkyl, (c) C₄₋₁₈ aryl, and (d) C₁₋₆ alkyl-C₄₋₁₈ aryl (e.g.,-L-R, in which L is C₁₋₆ alkyl and R is C₄₋₁₈ aryl); (38) —(CH₂)ᵣSO₂R¹, where r is an integer of from zero to four and where R¹ is selected from the group consisting of (a) C₁₋₆ alkyl, (b) C₄₋₁₈ aryl, and (c) C₁₋₆ alkyl-C₄₋₁₈ aryl (e.g.,-L-R, in which L is C₁₋₆ alkyl and R is C₄₋₁₈ aryl); (39) —(CH₂)ᵣSO₂NR¹R², where r is an integer of from zero to four and where each of R¹ and R² is, independently, selected from the group consisting of (a) hydrogen, (b) C₁₋₆ alkyl, (c) C₄₋₁₈ aryl, and (d) C₁₋₆ alkyl-C₄₋₁₈ aryl (e.g.,-L-R, in which L is C₁₋₆ alkyl and R is C₄₋₁₈ aryl); (40) —(CH₂)ᵣNR¹R², where r is an integer of from zero to four and where each of R¹ and R² is, independently, selected from the group consisting of (a) hydrogen, (b) an N-protecting group, (c) C₁₋₆ alkyl, (d) C₂₋₆ alkenyl, (e) C₂₋₆ alkynyl, (f) C₄₋₁₈ aryl, (g) C₁₋₆ alkyl-C₄₋₁₈ aryl (e.g.,-L-R, in which L is C₁₋₆ alkyl and R is C₄₋₁₈ aryl), (h) C₃₋₈ cycloalkyl, and (i) C₁₋₆ alkyl-C₃₋₈ cycloalkyl (e.g.,-L-R, in which L is C₁₋₆ alkyl and R is C₃₋₈ cycloalkyl), wherein in one embodiment no two groups are bound to the nitrogen atom through a carbonyl group or a sulfonyl group; (41) thiol (e.g., —SH); (42) perfluoroalkyl (e.g., —(CF₂)ₙCF₃, in which n is an integer from 0 to 10); (43) perfluoroalkoxy (e.g., —O—(CF₂)ₙCF₃, in which n is an integer from 0 to 10); (44) aryloxy (e.g., —O—R, in which R is aryl); (45) cycloalkoxy (e.g., —O—R, in which R is cycloalkyl); (46) cycloalkylalkoxy (e.g., —O-L-R, in which L is alkyl and R is cycloalkyl); and (47) arylalkoxy (e.g., —O-L-R, in which L is alkyl and R is aryl). In particular embodiments, an unsubstituted aryl group is a C₄₋₁₈, C₄₋₁₄, C₄₋₁₂, C₄₋₁₀, C₆₋₁₈, C₆₋₁₄, C₆₋₁₂, or C₆₋₁₀ aryl group.

By “arylalkoxy” is meant an alkyl-aryl group, as defined herein, attached to the parent molecular group through an oxygen atom. In some embodiments, the arylalkoxy group is —O-L-R, in which L is an alkyl group, as defined herein, and R is an aryl group, as defined herein.

By “aryloxy” is meant —OR, where R is an optionally substituted aryl group, as described herein. In some embodiments, an unsubstituted aryloxy group is a C₄₋₁₈ or C₆₋₁₈ aryloxy group.

By “aryloyl” is meant an aryl group that is attached to the parent molecular group through a carbonyl group. In some embodiments, an unsubstituted aryloyl group is a C₇₋₁₁ aryloyl or C₅₋₁₉ aryloyl group. In other embodiments, the aryloyl group is —C(O)—R, in which R is an aryl group, as defined herein.

By “azido” is meant an —N₃ group.

By “azidoalkyl” is meant an azido group attached to the parent molecular group through an alkyl group, as defined herein. In some embodiments, the azidoalkyl group is-L-N₃, in which L is an alkyl group, as defined herein. By “azo” is meant an —N═N-group.

By “carbene” is meant H₂C: and derivatives thereof having carbon bearing two nonbonding electrons or (C:). In some embodiments, the carbene is R¹R²(C:), where each of R¹ and R² is, independently, selected from aliphatic, hydrogen, heteroaliphatic, haloaliphatic, haloheteroaliphatic, aromatic, as defined herein, or any combination thereof, or R¹ and R², taken together with the atom to which each are attached, form a cycloaliphatic group, as defined herein.

By “carbenium cation” is meant H₃C⁺ and derivatives thereof having carbon bearing a +1 formal charge or C⁺. In some embodiments, the carbenium cation is R¹—C⁺(R)—R², where each of R, R¹, and R² is, independently, selected from hydrogen, aliphatic, heteroaliphatic, haloaliphatic, haloheteroaliphatic, aromatic, as defined herein, or any combination thereof, or R¹ and R² and optionally R, taken together with the atom to which each are attached, form a cycloaliphatic group, as defined herein.

By “carbonyl” is meant a —C(O)-group, which can also be represented as >C═O.

By “carboxyl” is meant a —CO₂H group or an anion thereof.

By “cyano” is meant a —CN group.

By “cycloaliphatic” is meant an aliphatic group, as defined herein, that is cyclic.

By “cycloalkoxy” is meant a cycloalkyl group, as defined herein, attached to the parent molecular group through an oxygen atom. In some embodiments, the cycloalkoxy group is —O—R, in which R is a cycloalkyl group, as defined herein.

By “cycloalkylalkoxy” is meant an alkyl-cycloalkyl group, as defined herein, attached to the parent molecular group through an oxygen atom. In some embodiments, the cycloalkylalkoxy group is —O-L-R, in which L is an alkyl group, as defined herein, and R is a cycloalkyl group, as defined herein.

By “cycloalkyl” is meant a monovalent saturated or unsaturated non-aromatic cyclic hydrocarbon group of from three to eight carbons, unless otherwise specified, and is exemplified by cyclopropyl, cyclobutyl, cyclopentyl, cyclohexyl, cycloheptyl, bicyclo[2.2.1.heptyl, and the like. The cycloalkyl group can also be substituted or unsubstituted. For example, the cycloalkyl group can be substituted with one or more groups including those described herein for alkyl.

By “cycloheteroaliphatic” is meant a heteroaliphatic group, as defined herein, that is cyclic.

By “ester” is meant —C(O)OR or —OC(O)R, where R is selected from aliphatic, heteroaliphatic, haloaliphatic, haloheteroaliphatic, aromatic, as defined herein, or any combination thereof.

By “halo” is meant F, Cl, Br, or I.

By “haloaliphatic” is meant an aliphatic group, as defined herein, in which one or more hydrogen atoms, such as one to 10 hydrogen atoms, independently is replaced with a halogen atom, such as fluoro, bromo, chloro, or iodo.

By “haloalkyl” is meant an alkyl group, as defined herein, where one or more hydrogen atoms, such as one to 10 hydrogen atoms, independently is replaced with a halogen atom, such as fluoro, bromo, chloro, or iodo. In an independent embodiment, haloalkyl can be a —CX₃ group, wherein each X independently can be selected from fluoro, bromo, chloro, or iodo. In some embodiments, the haloalkyl group is-L-X, in which L is an alkyl group, as defined herein, and X is fluoro, bromo, chloro, or iodo. In other embodiments, the halooalkyl group is-L-C(X)(R¹)—R², in which L is a covalent bond or an alkyl group, as defined herein; X is fluoro, bromo, chloro, or iodo; and each of R¹ and R² is, independently, H or alkyl, as defined herein.

By “haloheteroaliphatic” is meant a heteroaliphatic, as defined herein, in which one or more hydrogen atoms, such as one to 10 hydrogen atoms, independently is replaced with a halogen atom, such as fluoro, bromo, chloro, or iodo.

By “heteroaliphatic” is meant an aliphatic group, as defined herein, including at least one heteroatom to 20 heteroatoms, such as one to 15 heteroatoms, or one to 5 heteroatoms, which can be selected from, but not limited to oxygen, nitrogen, sulfur, silicon, boron, selenium, phosphorous, and oxidized forms thereof within the group.

By “heteroalkyl,” “heteroalkenyl,” and “heteroalkynyl” is meant an alkyl, alkenyl, or alkynyl group (which can be branched, straight-chain, or cyclic), respectively, as defined herein, including at least one heteroatom to 20 heteroatoms, such as one to 15 heteroatoms, or one to 5 heteroatoms, which can be selected from, but not limited to, oxygen, nitrogen, sulfur, silicon, boron, selenium, phosphorous, and oxidized forms thereof within the group.

By “heteroalkyl-aryl,” “heteroalkenyl-aryl,” and “heteroalkynyl-aryl” is meant an aryl group, as defined herein, that is or can be coupled to a compound disclosed herein, where the aryl group is or becomes coupled through a heteroalkyl, heteroalkenyl, or heteroalkynyl group, respectively, as defined herein. In some embodiments, the heteroalkyl-aryl group is-L-R, in which L is a heteroalkyl group, as defined herein, and R is an aryl group, as defined herein. In some embodiments, the heteroalkenyl-aryl group is-L-R, in which L is a heteroalkenyl group, as defined herein, and R is an aryl group, as defined herein. In some embodiments, the heteroalkynyl-aryl group is-L-R, in which L is a heteroalkynyl group, as defined herein, and R is an aryl group, as defined herein.

By “heteroalkyl-heteroaryl,” “heteroalkenyl-heteroaryl,” and “heteroalkynyl-heteroaryl” is meant a heteroaryl group, as defined herein, that is or can be coupled to a compound disclosed herein, where the heteroaryl group is or becomes coupled through a heteroalkyl, heteroalkenyl, or heteroalkynyl group, respectively, as defined herein. In some embodiments, the heteroalkyl-heteroaryl group is-L-R, in which L is a heteroalkyl group, as defined herein, and R is a heteroaryl group, as defined herein. In some embodiments, the heteroalkenyl-heteroaryl group is-L-R, in which L is a heteroalkenyl group, as defined herein, and R is a heteroaryl group, as defined herein. In some embodiments, the heteroalkynyl-heteroaryl group is-L-R, in which L is a heteroalkynyl group, as defined herein, and R is a heteroaryl group, as defined herein.

By “heteroaryl” is meant an aryl group including at least one heteroatom to six heteroatoms, such as one to four heteroatoms, which can be selected from, but not limited to, oxygen, nitrogen, sulfur, silicon, boron, selenium, phosphorous, and oxidized forms thereof within the ring. Such heteroaryl groups can have a single ring or multiple condensed rings, where the condensed rings may or may not be aromatic and/or contain a heteroatom, provided that the point of attachment is through an atom of the aromatic heteroaryl group. Heteroaryl groups may be substituted with one or more groups other than hydrogen, such as aliphatic, heteroaliphatic, aromatic, other functional groups, or any combination thereof. An example heteroaryl includes a subset of heterocyclyl groups, as defined herein, which are aromatic, i.e., they contain 4n+2 pi electrons within the mono- or multicyclic ring system.

By “heteroatom” is meant an atom other than carbon, such as oxygen, nitrogen, sulfur, silicon, boron, selenium, or phosphorous. In particular disclosed embodiments, such as when valency constraints do not permit, a heteroatom does not include a halogen atom.

By “heterocyclyl” is meant a 5- , 6- or 7-membered ring, unless otherwise specified, containing one, two, three, or four non-carbon heteroatoms (e.g., independently selected from the group consisting of nitrogen, oxygen, phosphorous, sulfur, or halo). The 5-membered ring has zero to two double bonds and the 6- and 7-membered rings have zero to three double bonds. The term “heterocyclyl” also includes bicyclic, tricyclic and tetracyclic groups in which any of the above heterocyclic rings is fused to one, two, or three rings independently selected from the group consisting of an aryl ring, a cyclohexane ring, a cyclohexene ring, a cyclopentane ring, a cyclopentene ring, and another monocyclic heterocyclic ring, such as indolyl, quinolyl, isoquinolyl, tetrahydroquinolyl, benzofuryl, benzothienyl and the like. Heterocyclics include thiiranyl, thietanyl, tetrahydrothienyl, thianyl, thiepanyl, aziridinyl, azetidinyl, pyrrolidinyl, piperidinyl, azepanyl, pyrrolyl, pyrrolinyl, pyrazolyl, pyrazolinyl, pyrazolidinyl, imidazolyl, imidazolinyl, imidazolidinyl, pyridyl, homopiperidinyl, pyrazinyl, piperazinyl, pyrimidinyl, pyridazinyl, oxazolyl, oxazolidinyl, oxazolidonyl, isoxazolyl, isoxazolidiniyl, morpholinyl, thiomorpholinyl, thiazolyl, thiazolidinyl, isothiazolyl, isothiazolidinyl, indolyl, quinolinyl, isoquinolinyl, benzimidazolyl, benzothiazolyl, benzoxazolyl, furyl, thienyl, thiazolidinyl, isothiazolyl, isoindazoyl, triazolyl, tetrazolyl, oxadiazolyl, uricyl, thiadiazolyl, pyrimidyl, tetrahydrofuranyl, dihydrofuranyl, dihydrothienyl, dihydroindolyl, tetrahydroquinolyl, tetrahydroisoquinolyl, pyranyl, dihydropyranyl, tetrahydropyranyl, dithiazolyl, dioxanyl, dioxinyl, dithianyl, trithianyl, oxazinyl, thiazinyl, oxothiolanyl, triazinyl, benzofuranyl, benzothienyl, and the like.

By “heterocyclyloxy” is meant a heterocyclyl group, as defined herein, attached to the parent molecular group through an oxygen atom. In some embodiments, the heterocyclyloxy group is —O—R, in which R is a heterocyclyl group, as defined herein.

By “heterocyclyloyl” is meant a heterocyclyl group, as defined herein, attached to the parent molecular group through a carbonyl group. In some embodiments, the heterocyclyloyl group is —C(O)—R, in which R is a heterocyclyl group, as defined herein.

By “hydroxyl” is meant —OH.

By “hydroxyalkyl” is meant an alkyl group, as defined herein, substituted by one to three hydroxyl groups, with the proviso that no more than one hydroxyl group may be attached to a single carbon atom of the alkyl group and is exemplified by hydroxymethyl, dihydroxypropyl, and the like. In some embodiments, the hydroxyalkyl group is-L-OH, in which L is an alkyl group, as defined herein. In other embodiments, the hydroxyalkyl group is-L-C(OH)(R¹)—R², in which L is a covalent bond or an alkyl group, as defined herein, and each of R¹ and R² is, independently, H or alkyl, as defined herein.

By “ketone” is meant —C(O)R, where R is selected from aliphatic, heteroaliphatic, aromatic, as defined herein, or any combination thereof.

By “nitro” is meant an —NO₂ group.

By “nitroalkyl” is meant an alkyl group, as defined herein, substituted by one to three nitro groups. In some embodiments, the nitroalkyl group is-L-NO, in which L is an alkyl group, as defined herein. In other embodiments, the nitroalkyl group is-L-C(NO)(R¹)—R², in which L is a covalent bond or an alkyl group, as defined herein, and each of R¹ and R² is, independently, H or alkyl, as defined herein.

By “oxo” is meant an ═O group.

By “oxy” is meant —O—.

By “perfluoroalkyl” is meant an alkyl group, as defined herein, having each hydrogen atom substituted with a fluorine atom. Example perfluoroalkyl groups include trifluoromethyl, pentafluoroethyl, etc. In some embodiments, the perfluoroalkyl group is —(CF₂)ₙCF₃, in which n is an integer from 0 to 10.

By “perfluoroalkoxy” is meant an alkoxy group, as defined herein, having each hydrogen atom substituted with a fluorine atom. In some embodiments, the perfluoroalkoxy group is —O—R, in which R is a perfluoroalkyl group, as defined herein.

By “salt” is meant an ionic form of a compound or structure (e.g., any formulas, compounds, or compositions described herein), which includes a cation or anion compound to form an electrically neutral compound or structure. Salts are well known in the art. For example, non-toxic salts are described in Berge S M et al., “Pharmaceutical salts,” J. Pharm. Sci. 1977 January; 66(1):1-19; and in “Handbook of Pharmaceutical Salts: Properties, Selection, and Use,” Wiley-VCH, April 2011 (2nd rev. ed., eds. P. H. Stahl and C. G. Wermuth. The salts can be prepared in situ during the final isolation and purification of the compounds of the invention or separately by reacting the free base group with a suitable organic acid (thereby producing an anionic salt) or by reacting the acid group with a suitable metal or organic salt (thereby producing a cationic salt). Representative anionic salts include acetate, adipate, alginate, ascorbate, aspartate, benzenesulfonate, benzoate, bicarbonate, bisulfate, bitartrate, borate, bromide, butyrate, camphorate, camphorsulfonate, chloride, citrate, cyclopentanepropionate, digluconate, dihydrochloride, diphosphate, dodecylsulfate, edetate, ethanesulfonate, fumarate, glucoheptonate, gluconate, glutamate, glycerophosphate, hemisulfate, heptonate, hexanoate, hydrobromide, hydrochloride, hydroiodide, hydroxyethanesulfonate, hydroxynaphthoate, iodide, lactate, lactobionate, laurate, lauryl sulfate, malate, maleate, malonate, mandelate, mesylate, methanesulfonate, methylbromide, methylnitrate, methylsulfate, mucate, 2-naphthalenesulfonate, nicotinate, nitrate, oleate, oxalate, palmitate, pamoate, pectinate, persulfate, 3-phenylpropionate, phosphate, picrate, pivalate, polygalacturonate, propionate, salicylate, stearate, subacetate, succinate, sulfate, tannate, tartrate, theophyllinate, thiocyanate, triethiodide, toluenesulfonate, undecanoate, valerate salts, and the like. Representative cationic salts include metal salts, such as alkali or alkaline earth salts, e.g., barium, calcium (e.g., calcium edetate), lithium, magnesium, potassium, sodium, and the like; other metal salts, such as aluminum, bismuth, iron, and zinc; as well as nontoxic ammonium, quaternary ammonium, and amine cations, including, but not limited to ammonium, tetramethylammonium, tetraethylammonium, methylamine, dimethylamine, trimethylamine, triethylamine, ethylamine, pyridinium, and the like. Other cationic salts include organic salts, such as chloroprocaine, choline, dibenzylethylenediamine, diethanolamine, ethylenediamine, methylglucamine, and procaine. Yet other salts include ammonium, sulfonium, sulfoxonium, phosphonium, iminium, imidazolium, benzimidazolium, amidinium, guanidinium, phosphazinium, phosphazenium, pyridinium, etc., as well as other cationic groups described herein (e.g., optionally substituted isoxazolium, optionally substituted oxazolium, optionally substituted thiazolium, optionally substituted pyrrolium, optionally substituted furanium, optionally substituted thiophenium, optionally substituted imidazolium, optionally substituted pyrazolium, optionally substituted isothiazolium, optionally substituted triazolium, optionally substituted tetrazolium, optionally substituted furazanium, optionally substituted pyridinium, optionally substituted pyrimidinium, optionally substituted pyrazinium, optionally substituted triazinium, optionally substituted tetrazinium, optionally substituted pyridazinium, optionally substituted oxazinium, optionally substituted pyrrolidinium, optionally substituted pyrazolidinium, optionally substituted imidazolinium, optionally substituted isoxazolidinium, optionally substituted oxazolidinium, optionally substituted piperazinium, optionally substituted piperidinium, optionally substituted morpholinium, optionally substituted azepanium, optionally substituted azepinium, optionally substituted indolium, optionally substituted isoindolium, optionally substituted indolizinium, optionally substituted indazolium, optionally substituted benzimidazolium, optionally substituted isoquinolinum, optionally substituted quinolizinium, optionally substituted dehydroquinolizinium, optionally substituted quinolinium, optionally substituted isoindolinium, optionally substituted benzimidazolinium, and optionally substituted purinium).

By “sulfo” is meant an —S(O)₂OH group.

By “sulfonyl” or “sulfonate” is meant an —S(O)₂-group or a —SO₂R, where R is selected from hydrogen, aliphatic, heteroaliphatic, haloaliphatic, haloheteroaliphatic, aromatic, as defined herein, or any combination thereof.

By “thioalkoxy” is meant an alkyl group, as defined herein, attached to the parent molecular group through a sulfur atom. Example unsubstituted thioalkoxy groups include C₁₋₆ thioalkoxy. In some embodiments, the thioalkoxy group is —S—R, in which R is an alkyl group, as defined herein.

By “thiol” is meant an —SH group.

A person of ordinary skill in the art would recognize that the definitions provided above are not intended to include impermissible substitution patterns (e.g., methyl substituted with 5 different groups, and the like). Such impermissible substitution patterns are easily recognized by a person of ordinary skill in the art. Any functional group disclosed herein and/or defined above can be substituted or unsubstituted, unless otherwise indicated therein.

### APPARATUS

The etching methods described herein can be carried out in a variety of apparatuses. A suitable apparatus includes a process chamber, a substrate holder in the process chamber configured to hold the substrate in place during etching, an inlet to the process chamber for introducing one or more reactants and a plasma generating mechanism configured for generating a plasma to activate one or more reactants in the process gas. In some cases, the etching apparatus also has the capability of performing deposition.

Examples of suitable apparatuses include, without limitation, inductively coupled plasma (ICP) reactors. Although ICP reactors are described herein in detail, it should be understood that capacitively coupled plasma reactors may also be used.

FIG. 1 schematically shows a cross-sectional view of an inductively coupled plasma integrated etching apparatus appropriate for implementing etching methods described herein, an example of which is a Kiyo® reactor, produced by Lam Research Corp. of Fremont, CA. The apparatus includes a chamber 132 that includes a chamber body 114, a chuck 116, and a dielectric window 106. The chamber 132 includes a processing region and the dielectric window 106 is disposed over the processing region. The chuck 116 can be an electrostatic chuck for supporting a substrate 112 and is disposed in the chamber below the processing region. In some embodiments, an internal Faraday shield (not shown) is disposed inside the chamber 100 beneath the dielectric window 106. A transformer coupled plasma (TCP) coil 134 is disposed over the dielectric window 106 and is connected to match circuitry 102.

The system includes a bias RF generator 120, which can be defined from one or more generators. If multiple generators are provided, different frequencies can be used to achieve various tuning characteristics. A bias match 118 is coupled between the RF generators 120 and a conductive plate of the assembly that defines the chuck 116. The chuck 116 also includes electrostatic electrodes to enable the chucking and dechucking of the wafer. Broadly, a filter and a DC clamp power supply can be provided. Other control systems for lifting the wafer from the chuck 116 can also be provided.

In various embodiments, a bias voltage of the electrostatic chuck may be set at about 50 Vb or may be set at a different bias voltage depending on the process performed in accordance with disclosed embodiments. For example, the bias voltage during plasma etch may be between about 20 Vb and about 100 Vb, or between about 30 Vb and about 150 Vb.

A first gas injector 104 provides two different channels to inject two separate streams of process gases or liquid precursor (in vapor form) to the chamber from the top of the chamber. It should be appreciated that multiple gas supplies may be provided for supplying different gases to the chamber for various types of operations, such as process operations on wafers, waferless auto-cleaning (WAC) operations, and other operations. A second gas injector 110 provides another gas stream that enters the chamber through the side instead of from the top.

Delivery systems 128 include, in one embodiment, an etch gas delivery system 127 and a liquid delivery system 129. Manifolds 122 are used for selecting, switching, and/or mixing outputs from the respective delivery systems. As will be described in more detail below, the etch gas delivery system is configured to output etchant gases that are optimized to etch one or more layers of materials of a substrate. The manifolds 122 are further optimized, in response to control from the controller 108, to perform plasma etching and declogging operations.

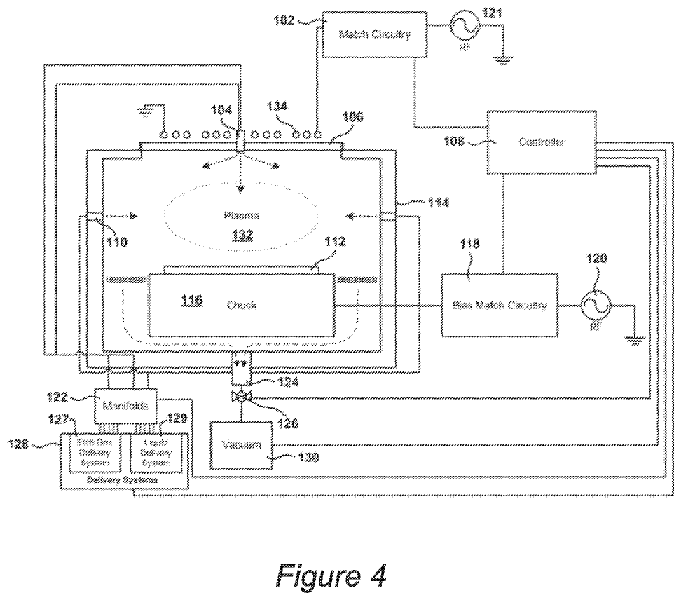

In the embodiment of FIG. 4, independent gas streams may be delivered into the chamber. One stream can be injected through a center of injector 104. A second stream can be injected also through injector 104, but via a different path that surrounds the center of injector 104. The third stream may be injected into the side of the chamber via side injector 110. In one embodiment, gas injector 104 also provides for optical access into the process chamber, for example, along an axial path from a diagnostic endpoint outside the process chamber through an optical access window.

The various ways of injecting gases into the chamber have been described to illustrate that the etch gases and/or the liquid precursor can be provided into the chamber from various locations. In some cases, only the injector 104 is used. In other cases, only the side injector 110 is used. In other cases, both the injector 104 and the side injector 110 may be used. In one configuration, manifolds 122 control which gases are supplied to each of the three different gas lines. Manifolds 122 allow for any type of gas to be provided to any of the three different gas lines. The gases may be sent into the chamber without mixing, or be mixed with other gases before introduction into the chamber. In some embodiments the halogen source and vaporized organic solvent are delivered to the process chamber via separate inlets. In other embodiments, they may be delivered via one inlet.

Referring back to FIG. 4, a vacuum pump 130 is connected to the chamber 132 to enable vacuum pressure control and removal of gaseous byproducts from the chamber during operational plasma processing. A valve 126 is disposed between exhaust 124 and the vacuum pump 130 to control the amount of vacuum suction being applied to the chamber.

The dielectric window 106 can include a ceramic material or a ceramic-type material. Other dielectric materials are also possible, so long as they are capable of withstanding the conditions of a semiconductor etching chamber. Typically, chambers operate at temperatures ranging between −60 degrees Celsius and approximately 250 degrees Celsius. The apparatus will also typically include a heater, and a temperature control mechanism. The temperature will depend on the etching process operation and specific recipe. The chamber 132 will also operate at vacuum conditions in the range of between about 1 mTorr (mT) and about 10 Torr.

Although not all specifically shown, chamber 132 is typically coupled to facilities when installed in either a clean room or a fabrication facility. Facilities include plumbing that provide, among other things, processing gases, vacuum, temperature control, and environmental particle control. These facilities are coupled to chamber 132, when installed in the target fabrication facility. Additionally, chamber 132 may be coupled to a transfer chamber that will enable robotics to transfer semiconductor wafers into and out of chamber 132 using automation.

A programmable controller 108 is provided for controlling the operation of the chamber 132 and its associated components. Broadly speaking, the controller 108 can be programmed to execute a chamber operation defined by a recipe. A given recipe may specify various parameters for the operation, such as the application of power to the TCP coils, the flow of gas into the chamber, and the application of vacuum. It should be appreciated that the timing, duration, magnitude, or any other adjustable parameter or controllable feature can be defined by a recipe and carried out by the controller to control the operation of the chamber 132 and its associated components. Additionally, a series of recipes may be programmed into the controller 108. In one embodiment, the recipe is configured to process etch operations and includes program instructions for performing any of the methods provided herein.

In some embodiments, a system controller 108 (which may include one or more physical or logical controllers) controls some or all of the operations of the process chamber. The system controller 108 may include one or more memory devices and one or more processors. In some embodiments, the apparatus includes a switching system for controlling flow rates of the process gases. The controller 108, in some embodiments, includes program instructions for causing the steps of any of the methods provided herein.

In some implementations, the system controller 108 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be integrated into the system controller 108, which may control various components or subparts of the system or systems. The system controller, depending on the processing parameters and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 108 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication or removal of one or more layers, materials, metals, oxides, silicon, silicon dioxide, surfaces, circuits, and/or dies of a wafer.

The system controller 108, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 430 receives instructions in the form of data, which specify parameters for each of the processing steps to be performed during one or more operations. It should be understood that the parameters may be specific to the type of process to be performed and the type of tool that the controller is configured to interface with or control. Thus, as described above, the system controller 108 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an ALE chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

In some embodiments the controller includes program instructions for: (i) on a semiconductor substrate having an exposed layer of a mask material, a recessed feature, and a layer of a target material undelying the layer of the mask material, where the target material is exposed at a bottom of the recessed feature, etching of the target material using a plasma etch, and thereby causing an increase in depth of the recessed feature; and (ii) etching a clogging material deposited during the plasma etch and narrowing or blocking the recessed feature, by contacting the semiconductor substrate with a halogen source and a vapor of a liquid selected from the group consisting of an organic solvent and water.

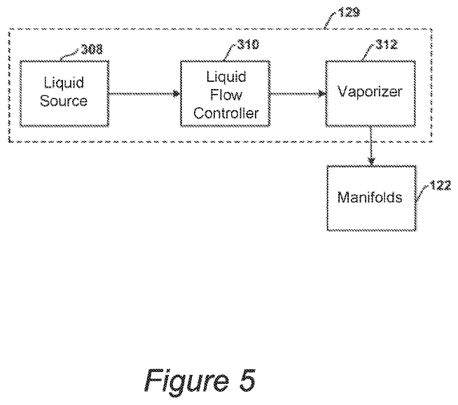

FIG. 5 is a schematic diagram that illustrates additional details of the liquid delivery system, in accordance with one embodiment. The liquid delivery system allows for delivering organic solvents and/or water to the process chamber in a vapor form. As shown in in FIG. 5, liquid delivery system 129 includes a source of liquid (e.g., solvent or water) 308, a liquid flow controller 310, and a vaporizer 312. The source of liquid 308 can be coupled in flow communication to facilities that provide suitable liquid solvents or water. As stated above, a variety of organic solvents, such as alkanes, ketones, and alcohols may be used. The liquid organic solvent or water flows from source 308 to liquid flow controller 310, which regulates the amount of flow based on instruction received from controller 108. The liquid flows from the liquid flow controller 310 to vaporizer 312, which converts the liquid solvent or water from the liquid state to the vapor state. The vaporized precursor flows to manifolds 122, which, based on control received from the controller 108, supplies the vaporized solvent or water to gas injector 104 (see, e.g., FIG. 4) at the appropriate time. The vaporized solvent or water flows through gas injector 104 into the chamber 132 defined by chamber body 114 (see, e.g., FIG. 4). In some embodiments the vaporized solvent and/or water are delivered to the process chamber via a first inlet, whereas the halogen source is delivered via a different inlet. In other embodiments, all components of the declogging mixture are delivered to the process chamber via a shared inlet.

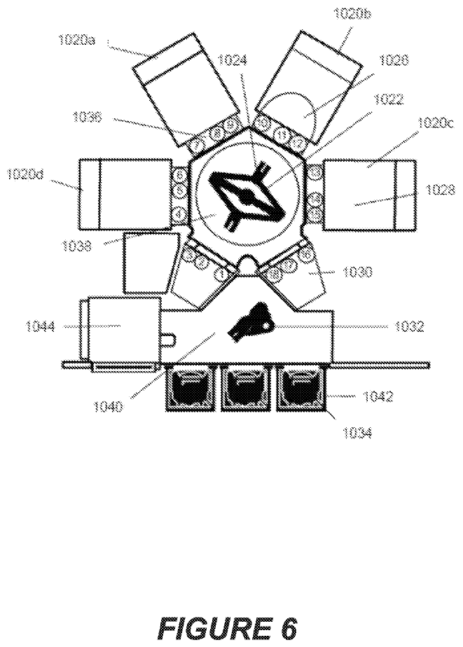

FIG. 6 depicts a semiconductor process cluster architecture with various modules that interface with a vacuum transfer module 1038 (VTM). The arrangement of various modules to “transfer” wafers among multiple storage facilities and processing modules may be referred to as a “cluster tool architecture” system. Airlock 1030, also known as a loadlock or transfer module, interfaces with the VTM 1038 which, in turn, interfaces with four processing modules 1020a-1020d, which may be individually optimized to perform various fabrication processes. By way of example, processing modules 1020a-1020d may be implemented to perform substrate etching, deposition, ion implantation, wafer cleaning, sputtering, and/or other semiconductor processes. In some embodiments, plasma etching of the target layer and patterning of the mask layer are performed in the same module. In some embodiments, plasma etching of the target layer and patterning of the mask layer are performed in different modules of the same tool. One or more of the substrate etching processing modules (any of 1020a-1020d) may be implemented as disclosed herein, e.g., for plasma etching of the target layer, and other suitable functions in accordance with the disclosed embodiments. Airlock 1030 and processing modules 1020a-1020d may be referred to as “stations.” Each station has a facet 1036 that interfaces the station to VTM 1038. Inside each facet, sensors 1-18 are used to detect the passing of wafer 1026 when moved between respective stations.

Robot 1022 transfers wafer 1026 between stations. In one embodiment, robot 1022 has one arm, and in another embodiment, robot 1022 has two arms, where each arm has an end effector 1024 to pick wafers such as wafer 1026 for transport. Front-end robot 1032, in atmospheric transfer module (ATM) 1040, is used to transfer wafers 1026 from cassette or Front Opening Unified Pod (FOUP) 1034 in Load Port Module (LPM) 1042 to airlock 1030. Module center 1028 inside processing modules 1020a-1020d is one location for placing wafer 1026. Aligner 1044 in ATM 1040 is used to align wafers.

In an exemplary processing method, a wafer is placed in one of the FOUPs 1034 in the LPM 1042. Front-end robot 1032 transfers the wafer from the FOUP 1034 to an aligner 1044, which allows the wafer 1026 to be properly centered before it is etched or processed. After being aligned, the wafer 1026 is moved by the front-end robot 1032 into an airlock 1030. Because the airlock 1030 has the ability to match the environment between an ATM 1040 and a VTM 1038, the wafer 1026 is able to move between the two pressure environments without being damaged. From the airlock 1030, the wafer 1026 is moved by robot 1022 through VTM 1038 and into one of the processing modules 1020a-1020d. In order to achieve this wafer movement, the robot 1022 uses end effectors 1024 on each of its arms. Once the wafer 1026 has been processed, it is moved by robot 1022 from the processing modules 1020a-520d to the airlock 1030. From here, the wafer 1026 may be moved by the front-end robot 1032 to one of the FOUPs 1034 or to the aligner 1044.

It should be noted that the computer controlling the wafer movement can be local to the cluster architecture, or can be located external to the cluster architecture in the manufacturing floor, or in a remote location and connected to the cluster architecture via a network. A controller as described above with respect to FIG. 4 may be implemented with the tool in FIG. 6. Machine-readable media containing instructions for controlling process operations in accordance with the present invention may be coupled to the system controller.

In some embodiments, a system for processing a semiconductor substrate includes one or more etch chambers; and a system controller having program instructions for conducting any of the processes or sub-processes described herein.

In some embodiments an apparatus is provided, where the apparatus includes a process chamber having a substrate holder configured for holding the semiconductor substrate during etching, and an inlet for introducing one or more reactants to the process chamber; optionally a plasma generator configured for generating a plasma in a process gas; and a controller. The controller includes program instructions for implementing any of the methods describing herein.

In another aspect a non-transitory computer machine-readable medium is provided, where it includes code for causing the performance of any of the methods described herein.

### FURTHER IMPLEMENTATIONS

The apparatus and processes described herein may be used in conjunction with lithographic patterning tools or processes, for example, for the fabrication or manufacture of semiconductor devices, displays, LEDs, photovoltaic panels, and the like. Typically, though not necessarily, such apparatus and processes will be used or conducted together in a common fabrication facility. Lithographic patterning of a film typically comprises some or all of the following steps, each step enabled with a number of possible tools: (1) application of photoresist on a work piece, i.e., a substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or work piece by using a dry or plasma-assisted etching tool; and (6) removing the resist using a tool such as an RF or microwave plasma resist stripper. In some embodiments these steps are performed in order to form a patterned mask layer prior to target layer etching.

1. A method of etching a material on a semiconductor substrate, the method comprising:
(a) providing a semiconductor substrate having an exposed layer of a mask material, a recessed feature, and a layer of a target material underlying the layer of the mask material, wherein the target material is exposed at the bottom of the recessed feature;
(b) etching the target material using a plasma etch, and thereby increasing depth of the recessed feature, wherein the etching of the target material results in narrowing or blocking of the recessed feature at least at one location due to deposition of a clogging material; and
(c) etching the clogging material by contacting the semiconductor substrate with a halogen source and a vapor of a liquid selected from the group consisting of an organic solvent and water.

2. The method of claim 1, wherein etching of the target material (b) and etching of the clogging material (c) are performed in one processing chamber.

3. The method of claim 1, wherein the clogging material comprises silicon oxide.

4. The method of claim 1, wherein the target material is selected from the group consisting of carbon and silicon.

5. The method of claim 1, wherein the mask material is selected from the group consisting of silicon oxynitride, silicon nitride, silicon oxide, silicon oxycarbide, silicon boride, boron-doped carbon, tungsten, tungsten-doped carbon, and boron-doped carbon.

6. The method of claim 1, wherein the etching of the clogging material has an etch selectivity of greater than 1 to both the mask material and the target material.

7. The method of claim 1, wherein the etching of the clogging material is performed in an absence of plasma.

8. The method of claim 1, wherein the etching of the clogging material comprises activating at least one reactant in a plasma without externally biasing the semiconductor substrate.

9. The method of claim 1, further comprising repeating steps (b)-(c).

10. The method of claim 1, wherein the etching of the clogging material comprises simultaneously contacting the semiconductor substrate with the halogen source and the vapor of a liquid selected from the group consisting of the organic solvent and water.

11. The method of claim 1, wherein the etching of the clogging material comprises sequentially contacting the semiconductor substrate with the halogen source and the vapor of a liquid selected from the group consisting of the organic solvent and water.

12. The method of claim 1, wherein (c) further comprises contacting the semiconductor substrate with an additive selected from the group consisting of an amine, a heterocyclic compound, and a bifluoride source.

13. The method of claim 1, wherein the etching of the clogging material is conducted at a pressure of between about 0.01-10 Torr and a temperature of between about −60-250° C.

14. The method of claim 1, wherein the recessed feature of the semiconductor substrate provided in (a) has a width of about 5-300 nm.

15. The method of any of claim 1, wherein the semiconductor substrate comprises a device selected from the group consisting of a partially fabricated 3D NAND device, a DRAM device, and a logic device.

16. The method of claim 1, wherein an aspect ratio of the recessed feature after completion of the etching is at least about 5:1.

17. The method of claim 1, wherein the solvent is selected from the group consisting of an alkane, a ketone, and an alcohol.

18. The method of claim 1, wherein the halogen source is selected from the group consisting of nitrogen tribromide (NBr₃). nitrogen trichloride (NCl₃), chlorine trifluoride (ClF₃), hydrogen fluoride (HF), hydrogen chloride (HCl), and hydrogen bromide (HBr).

19. The method of claim 1, wherein the plasma etch in (b) comprises contacting the substrate with an oxygen-containing reactant.

20. The method of claim 1, further comprising the steps of:
applying photoresist to the semiconductor substrate;
exposing the photoresist to light;
patterning the photoresist and transferring the pattern to the semiconductor substrate;
and selectively removing the photoresist from the semiconductor substrate.

21. A method of etching a material on a semiconductor substrate, the method comprising:
(a) providing a semiconductor substrate having an exposed layer of a mask material, a recessed feature, and a layer of a target material underlying the layer of the mask material, wherein the target material is exposed at the bottom of the recessed feature, wherein the mask material is a silicon-containing material, and wherein the target material is selected from the group consisting of carbon (C) and silicon (Si);
(b) etching the target material using an oxygen-containing plasma etch, and thereby increasing depth of the recessed feature, wherein the etching of the target material results in narrowing or blocking of the recessed feature at least at one location due to deposition of a silicon-containing clogging material; and
(c) etching the silicon-containing clogging material by contacting the semiconductor substrate with a halogen source and a vapor of a liquid selected from the group consisting of an organic solvent and water.

22. The method of claim 20, wherein the silicon-containing clogging material is silicon oxide.

23. An apparatus for processing a semiconductor substrate, the apparatus comprising:
(a) a process chamber configured for housing the semiconductor substrate, wherein the process chamber includes a substrate holder configured to hold the semiconductor substrate and an inlet configured to admit one or more reactants to the process chamber;
(b) a plasma generating mechanism;
(c) a mechanism for vaporising a liquid connected with the process chamber and configured for delivering the liquid to the process chamber; and
(d) a controller comprising program instructions configured to effect etching of a material on the semiconductor substrate by causing:
(i) on a semiconductor substrate comprising an exposed layer of a mask material, a recessed feature, and a layer of a target material undelying the layer of the mask material, wherein the target material is exposed at a bottom of the recessed feature, etching of the target material using a plasma etch, and thereby causing an increase in depth of the recessed feature; and
(ii) etching of a clogging material deposited during the plasma etch and narrowing or blocking the recessed feature, by causing contact of the semiconductor substrate with a halogen source and a vapor of a liquid selected from the group consisting of an organic solvent and water.

24. (canceled)

25. (canceled)
